(19) United States
(12) Patent Application Publication
(10) Pub. No.: US 2026/0222709 A1
(43) Pub. Date: Jul. 30, 2026

(54) PHOTODETECTION DEVICE AND COUNTER CIRCUIT

(71) Applicant: Sony Semiconductor Solutions Corporation, Kanagawa (JP)

(72) Inventors: Yasuji Ikeda, Kanagawa (JP); Takafumi Takatsuka, Kanagawa (JP); Kazuki Hizu, Kanagawa (JP); Iori Watanabe, Kanagawa (JP)

(21) Appl. No.: 19/150,090

(22) PCT Filed: Jan. 9, 2024
(86) PCT No.: PCT/JP24/00150

§ 371 Date: Jul. 22, 2025

(30) Foreign Application Priority Data
Mar. 3, 2023 (JP) 2023-032717

(51) Int. Cl. H04N 25/773

(52) U.S. Cl. CPC H04N 25/773

(57) ABSTRACT

An increase in the number of state transitions at a time of counting is suppressed. In one example, a photodetection device includes light receiving units that respectively output pulses generated in accordance with incidence of photons. A counter circuit counts the pulses from a respective light receiving unit. The counter circuit includes 2-bit Johnson counters whose states transition on a basis of a transition input. A second bit of a count output of a 2-bit Johnson counter at a preceding stage is used as the transition input of a 2-bit Johnson counter at a subsequent stage. The 2-bit Johnson counters may each include flip-flops connected in two stages, and in each of the plurality of 2-bit Johnson counters, an inverted value of an output of a flip-flop at a subsequent stage may be used as an input of a flip-flop at a preceding stage.

### TECHNICAL FIELD

The present technology relates to a photodetection device and a counter circuit. More specifically, the present technology relates to a photodetection device and a counter circuit in which 2-bit Johnson counters are connected in a plurality of stages.

### BACKGROUND ART

Counter circuits are used for various types of counting including counting of photons, particles, pulses, and time. For example, there has been proposed an image sensor that counts the number of photons incident to a photodiode during an exposure period and that outputs a count value of photons as a signal value (see, for example, Patent Document 1).

### CITATION LIST

### Patent Document

Patent Document 1: Japanese Patent Application Laid-Open No. 2019-129338

### SUMMARY OF THE INVENTION

### Problems to be Solved by the Invention

In the above-described conventional technique, however, since a binary counter is used as a counter circuit, the number of state transitions at a time of counting is large, and there is a possibility that power consumption increases.

The present technology has been made in view of such circumstances, and an object thereof is to suppress an increase in the number of state transitions at the time of counting.

### Solutions to Problems

The present technology has been made to solve the above-described problem, and a first aspect thereof is a photodetection device includes a light receiving unit that is arranged in a row direction and a column direction in a maritox and that outputs pulses generated in accordance with incidence of photons, and a counter circuit that counts the pulses output from the light receiving unit, in which the counter circuit includes a plurality of 2-bit Johnson counters whose states transition on a basis of a transition input, and a second bit of a count output of a 2-bit Johnson counter at a preceding stage is used as the transition input of a 2-bit Johnson counter at a subsequent stage. This brings about an effect of making a period of a state transition of the 2-bit Johnson counter at the subsequent stage longer than a period of a state transition of the 2-bit Johnson counter at the preceding stage.

In addition, in the first aspect, the 2-bit Johnson counters may each include flip-flops connected in two stages, and in each of the plurality of 2-bit Johnson counters, an inverted value of an output of a flip-flop at a subsequent stage may be used as an input of a flip-flop at a preceding stage. This brings about an effect of configuring the 2-bit Johnson counters using flip-flops connected in two stages.

In addition, in the first aspect, the photodetection device may further include an inverter connected between the output of the flip-flop at the subsequent stage and the input of the flip-flop at the preceding stage. This brings about an effect of using the inverted value of the output of the flip-flop at the subsequent stage as the input of the flip-flop at the preceding stage.

In addition, in the first aspect, the 2-bit Johnson counters may each include flip-flops connected in two stages, and in each of the plurality of 2-bit Johnson counters, a value held in a flip-flop at a subsequent stage as an inverted value of an output of the flip-flop at the subsequent stage may be used as an input of a flip-flop at a preceding stage. This brings about an effect of configuring the 2-bit Johnson counters using flip-flops connected in two stages and suppressing overwriting of the values held in the counter circuit.

In addition, in the first aspect, in each of the plurality of 2-bit Johnson counters, a value held in the flip-flop at the preceding stage as an inverted value of an output of the flip-flop at the preceding stage and the value held in the flip-flop at the subsequent stage as the inverted value of the output of the flip-flop at the subsequent stage may be used as an output of the counter circuit. This brings about an effect of configuring the 2-bit Johnson counters using flip-flops connected in two stages and outputting the values held in the counter circuit as count values.

In addition, in the first aspect, the flip-flop at the preceding stage may include a first latch circuit and a second latch circuit connected at a subsequent stage of the first latch circuit, and the flip-flop at the subsequent stage may include a third latch circuit and a fourth latch circuit connected at a subsequent stage of the third latch circuit. This brings about an effect of configuring the 2-bit Johnson counters using flip-flops connected in two stages.

In addition, in the first aspect, the first latch circuit may include a first inverter circuit that inverts an input, a second inverter circuit that is connected in anti-parallel to the first inverter circuit and that inverts an input on a basis of the transition input, and a first switch circuit that is connected at a preceding stage of the first inverter circuit and that opens and closes on a basis of the transition input, the second latch circuit may include a third inverter circuit that inverts an input, a fourth inverter circuit that is connected in anti-parallel to the third inverter circuit and that inverts an input on a basis of the transition input, and a second switch circuit that is connected at a preceding stage of the third inverter circuit and that opens and closes on a basis of the transition input, the third latch circuit may include a fifth inverter circuit that inverts an input, a sixth inverter circuit that is connected in anti-parallel to the fifth inverter circuit and that inverts an input based on the transition input, and a third switch circuit that is connected at a preceding stage of the fifth inverter circuit and that opens and closes on a basis of the transition input, and the fourth latch circuit may include a seventh inverter circuit that inverts an input, an eighth inverter circuit that is connected in antiparallel to the seventh inverter circuit and that inverts an input based on the transition input, and a fourth switch circuit that is connected at a preceding stage of the seventh inverter circuit and that opens and closes on a basis of the transition input. This brings about an effect of alternately repeating the state transition and the latch hold on the basis of the transition input in each flip-flop.

In addition, in the first aspect, each of the first and fifth inverter circuits may be a NAND circuit to which a reset signal is input, each of the third and seventh inverter circuits may be an inverter, each of the second, fourth, sixth, and eighth inverter circuits may be a clocked inverter, and each of the first to fourth switch circuits may be a transmission gate. This brings about an effect of alternately repeating the state transition and the latch hold on the basis of the transition input while enabling resetting of the count values.

In addition, in the first aspect, the photodetection device may further include a capacitor connected to an input terminal of the flip-flop at the preceding stage. This brings about an effect of stabilizing a value of a feedback path used for the 2-bit Johnson counter.

In addition, in the first aspect, a capacitance value of the capacitor may be larger than a capacitance value of a capacitor added to an output of the first switch circuit. This brings about an effect of enabling, in each 2-bit Johnson counter, feedback from the flip-flop at the subsequent stage to the flip-flop at the preceding stage and suppressing overwriting of the values held in the counter circuit.

In addition, in the first aspect, the capacitor may be a metal capacitor, a gate capacitor whose gate is connected to the input terminal of the flip-flop at the preceding stage, or a gate capacitor whose source/drain is connected to the input terminal of the flip-flop at the preceding stage. This brings about an effect of adding a capacitor to the input terminal of the flip-flop at the preceding stage.

Furthermore, in the first aspect, the capacitor may be a variable capacitor whose capacitance value is variable. This brings about an effect of making it possible to estimate a defect rate through extrapolation on the basis of a relationship between capacitance and the defect rate.

In addition, in the first aspect, each of the first and fifth inverter circuits may be a NAND circuit to which a reset signal is input, each of the third and seventh inverter circuits may be an inverter, each of the first switch circuit and the second, fourth, sixth, and eighth inverter circuits may be a clocked inverter, and each of the second to fourth switch circuits may be a transmission gate. This brings about an effect of using the value held in the flip-flop at the subsequent stage as the inverted value of the output of the flip-flop at the subsequent stage as the input of the flip-flop at the preceding stage while suppressing an increase in the number of elements.

In addition, in the first aspect, each of the first and fifth inverter circuits may be a NAND circuit to which a reset signal is input, each of the third and seventh inverter circuits may be an inverter, each of the second, fourth, and sixth inverter circuits may be a clocked inverter, the eighth inverter circuit may be a series circuit of an inverter and a transmission gate, and each of the first to fourth switch circuits may be a transmission gate. This brings about an effect of performing the latch holding on the basis of the transition input.

In addition, in the first aspect, each of the first and fifth inverter circuits may be a NAND circuit to which a reset signal is input, each of the third and seventh inverter circuits may be an inverter, each of the second and sixth inverter circuits may be a clocked inverter, each of the fourth and eighth inverter circuits may be a series circuit of an inverter and a transmission gate, and each of the first to fourth switch circuits may be a transmission gate. This brings about an effect of using the value held in the flip-flop at the subsequent stage as the inverted value of the output of the flip-flop at the subsequent stage as the input of the flip-flop at the preceding stage while ensuring layout symmetry.

In addition, in the first aspect, the pulses generated in accordance with the incidence of photons may be input to a first stage of the 2-bit Johnson counters. This brings about an effect of counting the number of photons incident on the light receiving unit.

In addition, in the first aspect, the number of states may be given as 4ⁿ, where n is the number of stages of the 2-bit Johnson counters. This brings about an effect of increasing the number of states as compared with a Johnson counter in which an output of a flip-flop at a last stage is fed back to an input of a flip-flop at a first stage.

Furthermore, in the first aspect, the counter circuit may be disposed below the light receiving unit. This brings about an effect of forming a counter circuit for each light receiving unit while suppressing an increase in planar size of the imaging device.

In addition, a second aspect is a counter circuit including a plurality of 2-bit Johnson counters whose states transition on a basis of a transition input, in which a second bit of a count output of a 2-bit Johnson counter at a preceding stage is used as the transition input of a 2-bit Johnson counter at a subsequent stage. This brings about an effect of making a period of a state transition of the 2-bit Johnson counter at the subsequent stage longer than a period of a state transition of the 2-bit Johnson counter at the preceding stage.

### BRIEF DESCRIPTION OF DRAWINGS

FIG. 1 is a block diagram illustrating a configuration example of a camera for which an imaging device according to a first embodiment is employed.

FIG. 2 is a block diagram illustrating a configuration example of a solid-state imaging device according to the first embodiment.

FIG. 3 is a circuit diagram illustrating a configuration example of a pixel according to the first embodiment.

FIG. 4 is a block diagram illustrating a configuration example of a counter circuit according to the first embodiment.

FIG. 5 is a circuit diagram illustrating a configuration example of a 2-bit Johnson counter according to the first embodiment.

FIG. 6 is a timing chart illustrating an output operation of the counter circuit according to the first embodiment.

FIG. 7 is a circuit diagram illustrating a configuration example of a counter circuit according to a second embodiment.

FIG. 8 is a timing chart illustrating an internal state and an output operation of the counter circuit according to the second embodiment.

FIG. 9 is a diagram illustrating comparison of state transitions of the counter circuit according to the second embodiment with those in a comparative example.

FIG. 10 is a circuit diagram illustrating a configuration example of a counter circuit according to a third embodiment.

FIG. 11 is a circuit diagram illustrating a first example of a counter circuit according to a fourth embodiment.

FIG. 12 is a circuit diagram illustrating an example of a capacitor in a foodback path of the counter circuit according to the fourth embodiment.

FIG. 13 is a circuit diagram illustrating an example of a change in a potential in the foodback path of the counter circuit according to the fourth embodiment.

FIG. 14 is a circuit diagram illustrating a second example of the counter circuit according to the fourth embodiment.

FIG. 15 is a circuit diagram illustrating a third example of the counter circuit according to the fourth embodiment.

FIG. 16 is a circuit diagram illustrating a fourth example of the counter circuit according to the fourth embodiment.

FIG. 17 is a plan view illustrating a layout example of the counter circuit according to the fourth embodiment.

FIG. 18 is a circuit diagram illustrating a configuration example of a counter circuit according to a fifth embodiment.

FIG. 19 is a plan view illustrating a layout example of a 2-bit Johnson counter according to the fifth embodiment.

FIG. 20 is a circuit diagram illustrating a configuration example of a counter circuit according to a sixth embodiment.

FIG. 21 is a plan view illustrating a layout example of a 2-bit Johnson counter according to the sixth embodiment.

FIG. 22 is a circuit diagram illustrating a configuration example of a counter circuit according to a seventh embodiment.

FIG. 23 is a perspective view illustrating a layout example of a solid-state imaging device according to an eighth embodiment.

FIG. 24 is a perspective view illustrating a layout example of a solid-state imaging device according to a ninth embodiment.

FIG. 25 is a circuit diagram illustrating a configuration example of a pixel according to a tenth embodiment.

FIG. 26 is a block diagram illustrating a configuration example of a distance measuring device according to an eleventh embodiment.

FIG. 27 is a block diagram illustrating a schematic configuration example of a vehicle control system.

FIG. 28 is an explanatory diagram illustrating an example of an installation position of an imaging section.

### MODE FOR CARRYING OUT THE INVENTION

Modes for carrying out the present technology (hereinafter referred to as embodiments) will be described hereinafter. The description will be given in the following order.

1. First Embodiment (an example in which a second bit of a count output of a 2-bit Johnson counter at a preceding stage is used as a transition input of a 2-bit Johnson counter at a subsequent stage)

2. Second Embodiment (an example in which an output of a clocked inverter of a latch circuit at a subsequent stage of a flip-flop at a subsequent stage is fed back to a flip-flop at a preceding stage in a 2-bit Johnson counter)

3. Third Embodiment (an example in which a clocked inverter is used at an input of a latch circuit at a preceding stage of a flip-flop at a preceding stage in a 2-bit Johnson counter)

4. Fourth Embodiment (an example in which an output of a clocked inverter of a latch circuit at a subsequent stage of a flip-flop at a subsequent stage is fed back to a flip-flop at a preceding stage and a capacitor is added to the feedback in a 2-bit Johnson counter)

5. Fifth Embodiment (an example in which an output of an inverter used as an input of a transmission gate of a latch circuit at a subsequent stage of a flip-flop at a subsequent stage is fed back to a flip-flop at a preceding stage in a 2-bit Johnson counter)

6. Sixth Embodiment (an example in which a transmission gate and an inverter are used instead of clocked inverters of a latch circuit at a subsequent stage of a flip-flop at a preceding stage and a latch circuit at a subsequent stage of a flip-flop at a subsequent stage in a 2-bit Johnson counter)

7. Seventh Embodiment (an example in which a value held in a flip-flop as an inverted value of an output of the flip-flop is used as an output of a counter circuit)

8. Eighth Embodiment (an example in which a pixel array unit of a solid-state imaging device is provided on an upper layer chip and a circuit array unit is provided on a lower layer chip)

9. Ninth Embodiment (an example in which a solid-state imaging device is formed on one chip)

10. Tenth Embodiment (an example in which a light receiving element of each pixel is provided on an upper layer chip and circuit units are provided on a lower layer chip)

11. Eleventh Embodiment (an example in which a counter circuit is employed for a distance measuring device)

12. Example of Application to Mobile Body

### 1. First Embodiment

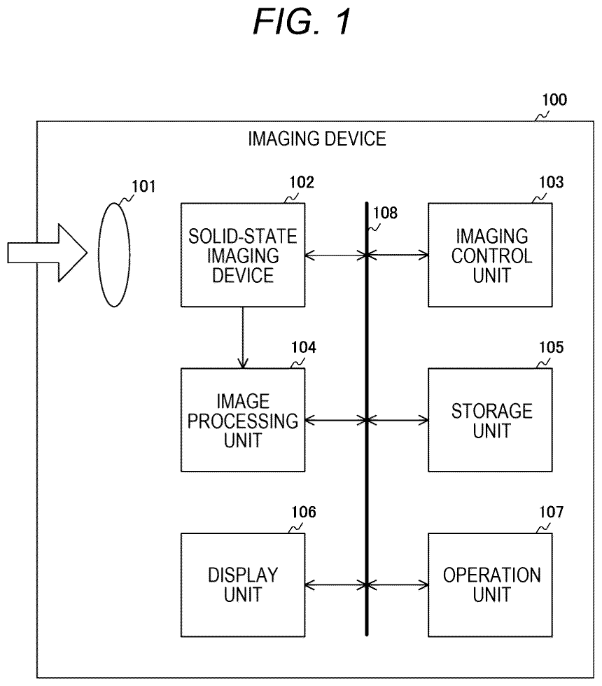

FIG. 1 is a block diagram illustrating a configuration example of a camera for which an imaging device according to a first embodiment is employed.

In the drawing, an imaging device 100 includes an optical system 101, a solid-state imaging device 102, an imaging control unit 103, an image processing unit 104, a storage unit 105, a display unit 106, and an operation unit 107. The imaging control unit 103, the image processing unit 104, the storage unit 105, the display unit 106, and the operation unit 107 are connected to one another via a bus 108. Note that the imaging device 100 may be used alone, may be incorporated into a portable terminal such as a smartphone, or may be incorporated into an authentication device or a monitoring device.

The optical system 101 causes light from a subject to enter the solid-state imaging device 102, and forms an image of the subject on a light receiving surface of the solid-state imaging device 102. The optical system 101 can include, for example, a focus lens, a zoom lens, a diaphragm, and the like. The optical system 101 may include a plurality of lenses such as a wide-angle lens, a standard lens, and a telephoto lens.

The solid-state imaging device 102 converts light from the subject into an electric signal for each pixel, and digitizes and outputs the electric signal. The solid-state imaging device 102 may be, for example, an event-based vision sensor. The light received by the solid-state imaging device 102 may be visible light, near infrared light (NIR), short wavelength infrared light (SWIR), ultraviolet light, X-rays, or the like.

The imaging control unit 103 controls the imaging by the solid-state imaging device 102 on the basis of a command from the operation unit 107. At this time, the imaging control unit 103 can control exposure conditions, imaging timing, and the like of the solid-state imaging device 102.

The image processing unit 104 performs image processing on the basis of the output from the solid-state imaging device 102. The image processing unit 104 may include an application processor that executes processing on the basis of software.

The storage unit 105 stores a captured image captured by the solid-state imaging device 102, and stores imaging parameters and the like of the solid-state imaging device 102. Furthermore, the storage unit 105 can store a program for operating the imaging device 100 on the basis of software. The storage unit 105 may include a read only memory (ROM), a random access memory (RAM), and a memory card.

The display unit 106 displays a captured image and displays various types of information supporting the imaging operation. The display unit 106 may be a liquid crystal display or an organic electro luminescence (EL) display.

The operation unit 107 provides a user interface for operating the imaging device 100. The operation unit 107 may include, for example, a button, a dial, and a switch provided in the imaging device 100. The operation unit 107 may be implemented as a touch panel along with the display unit 106.

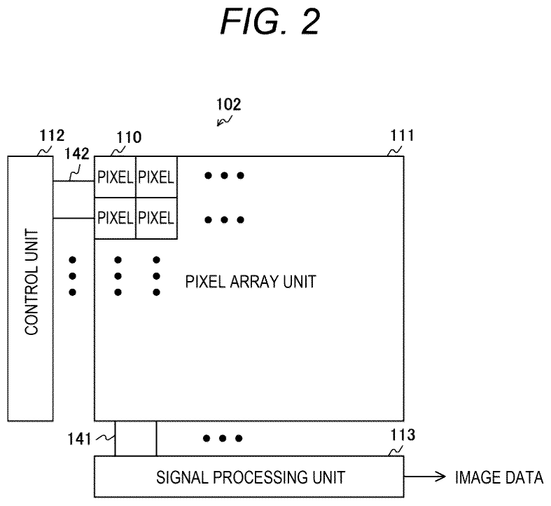

FIG. 2 is a block diagram illustrating a configuration example of the solid-state imaging device according to the first embodiment.

In the drawing, the solid-state imaging device 102 includes a control unit 112, a pixel array unit 111, and a signal processing unit 113. These circuits may be arranged in a single semiconductor substrate or may be arranged in a multilayer substrate.

In the pixel array unit 111, pixels 110 are arranged in a maritox shape in a row direction and a column direction. The pixel 110 outputs, as pixel data, a result of counting of pulses generated in accordance with incidence of photons. At this time, the pixel 110 can include a light receiving unit and a counter circuit. The counter circuit may be disposed below the light receiving unit. The light receiving unit may include a single photon avalanche diode (SPAD). The control unit 112 sequentially selects rows in synchronization with a vertical synchronization signal. The control unit 112 may include an arbitration circuit that arbitrates selection of a row including a pixel 110 in which an event has been detected. The signal processing unit 113 executes various types of signal processing on image data in which pixel data is arranged. The signal processing unit 113 may include a line scanner that scans columns. The signal processing unit 113 may include an arbitration circuit that arbitrates selection of a column including a pixel 110 in which an event has been detected.

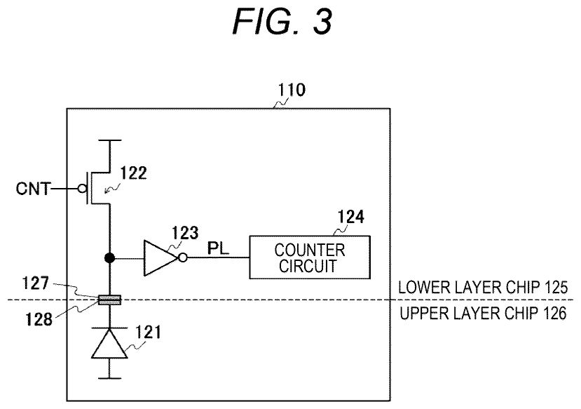

FIG. 3 is a circuit diagram illustrating a configuration example of the pixel according to the first embodiment.

In the drawing, the pixel 110 includes a SPAD 121, a quench resistor 122, an inverter 123, and a counter circuit 124.

The SPAD 121 detects photons one by one. At this time, the SPAD 121 can amplify a current on the basis of avalanche amplification. In the SPAD 121, however, a reverse voltage higher than a breakdown voltage is set. At this time, an amplification factor of the avalanche amplification is theoretically infinite. For this reason, the SPAD 121 can generate a saturation output current without depending on the amount of photons incident in unit time, and can detect photons one by one.

The quench resistor 122 forcibly stops the avalanche amplification of the SPAD 121. The quench resistor 122 may use a resistance component of a MOS transistor. At this time, a resistance value of the quench resistor 122 can be set on the basis of a control signal CNT applied to a gate of the MOS transistor. A reverse voltage higher than the breakdown voltage is set for the SPAD 121 via the quench resistor 122. For this reason, when a current flows through the SPAD 121 on the basis of the avalanche amplification, the voltage applied to the SPAD 121 decreases on the basis of the voltage drop by the quench resistor 122, and the avalanche amplification stops.

The inverter 123 generates pulses PL on the basis of a cathode voltage during an avalanche amplification operation of the SPAD 121 and outputs the pulses PL to the counter circuit 124.

The counter circuit 124 counts the pulses PL output from the inverter 123. The counter circuit 124 includes a plurality of 2-bit Johnson counters whose states transition on the basis of transition inputs. At this time, the counter circuit 124 can use a second bit of a count output of a 2-bit Johnson counter at a preceding stage as a transition input of a 2-bit Johnson counter at a subsequent stage.

The pixel 110 may be formed in a multilayer chip. At this time, the SPAD 121 may be formed in the upper layer chip 126, and the quench resistor 122, the inverter 123, and the counter circuit 124 may be formed in the lower layer chip 125.

The lower layer chip 125 and the upper layer chip 126 may be directly bonded to each other. At this time, pad electrodes 127 and 128 can be formed in the lower layer chip 125 and the upper layer chip 126, respectively. The pad electrode 127 is connected to the quench resistor 122 and the inverter 123. The pad electrode 128 is connected to the SPAD 121. The pad electrodes 127 and 128 can be disposed in such a way as to face each other. In the direct bonding of the lower layer chip 125 and the upper layer chip 126, hybrid bonding can be used. At this time, the pad electrodes 127 and 128 can be Cu—Cu connected. A material of semiconductor substrates used for the lower layer chip 125 and the upper layer chip 126 may be Si, InGaAs, or InP.

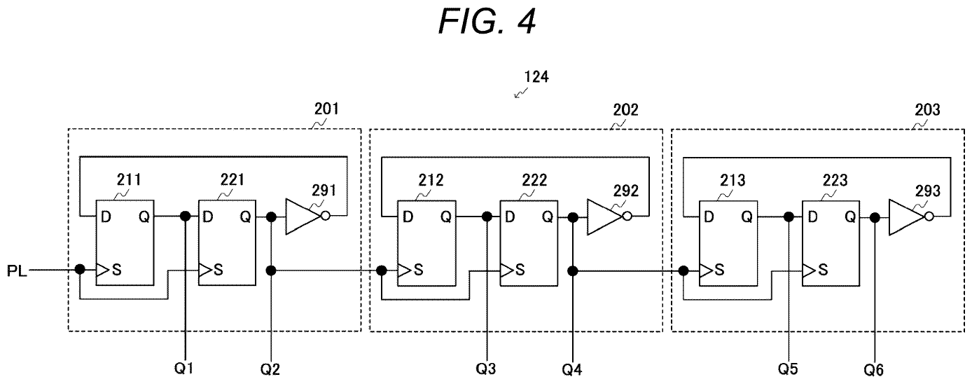

FIG. 4 is a block diagram illustrating a configuration example of the counter circuit according to the first embodiment. In the drawing, a configuration in which 2-bit Johnson counters 201 to 203 are connected in three stages is taken as an example of the counter circuit, but any configuration may be employed as long as 2-bit Johnson counters are connected in n (n is an integer of 2 or more) stages.

In the drawing, the counter circuit 124 includes a plurality of 2-bit Johnson counters 201 to 203. The pulses PL are input to the 2-bit Johnson counter 201 as a transition input S, and count values Q1 and Q2 are output from the 2-bit Johnson counter 201. A count value Q2 of a second bit of the 2-bit Johnson counter 201 at the preceding stage is input to the 2-bit Johnson counter 202 as a transition input S, and count values Q3 and Q4 are output from the 2-bit Johnson counter 202. A count value Q4 of a second bit of the 2-bit Johnson counter 202 at the preceding stage is input to the 2-bit Johnson counter 203 as a transition input S, and count values Q5 and Q6 are output from the 2-bit Johnson counter 203.

The 2-bit Johnson counter 201 includes flip-flops 211 and 221 and an inverter 291. The flip-flop 221 is connected at a subsequent stage of the flip-flop 211, and the inverter 291 is connected at a subsequent stage of the flip-flop 221. A data output Q of the flip-flop 221 is fed back to a data input D of the flip-flop 211 via the inverter 291. The pulses PL are input as a transition input S of each of the flip-flops 211 and 221.

The 2-bit Johnson counter 202 includes flip-flops 212 and 222 and an inverter 292. The flip-flop 222 is connected at a subsequent stage of the flip-flop 212, and the inverter 292 is connected at a subsequent stage of the flip-flop 222. A data output Q of the flip-flop 222 is fed back to a data input D of the flip-flop 212 via the inverter 292. The count value Q2 of the second bit of the 2-bit Johnson counter 201 at the preceding stage is input as a transition input S of each of the flip-flops 212 and 222.

The 2-bit Johnson counter 203 includes flip-flops 213 and 223 and an inverter 293. The flip-flop 223 is connected at a subsequent stage of the flip-flop 213, and the inverter 293 is connected at a subsequent stage of the flip-flop 223. A data output Q of the flip-flop 223 is fed back to a data input D of the flip-flop 213 via the inverter 293. The count value Q4 of the second bit of the 2-bit Johnson counter 202 at the preceding stage is input as a transition input S of each of the flip-flops 213 and 223.

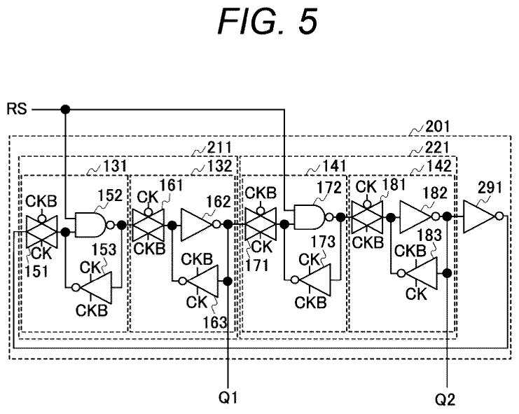

FIG. 5 is a circuit diagram illustrating a configuration example of the 2-bit Johnson counter according to the first embodiment. Note that the drawing illustrates a configuration example of the 2-bit Johnson counter 201 in FIG. 4.

In the drawing, the flip-flop 211 includes latch circuits 131 and 132. The latch circuit 132 is connected at a subsequent stage of the latch circuit 131. The flip-flop 221 includes latch circuits 141 and 142. The latch circuit 142 is connected at a subsequent stage of the latch circuit 141.

The latch circuit 131 includes a transmission gate 151, a NAND circuit 152, and a clocked inverter 153. A reset signal RS is input to a first input terminal of the NAND circuit 152, and the transmission gate 151 is connected to a second input terminal of the NAND circuit 152. The clocked inverter 153 is connected in anti-parallel to the NAND circuit 152. The count value Q2 is input to the transmission gate 151 via the inverter 291. A clock CK and an inverted clock CKB are input to the transmission gate 151 and the clocked inverter 153 as transition inputs. The clock CK and the inverted clock CKB have phases opposite to each other. The pulses PL may be input as the clock CK.

The latch circuit 132 includes a transmission gate 161, an inverter 162, and a clocked inverter 163. The transmission gate 161 is connected to an input terminal of the inverter 162. The clocked inverter 163 is connected in anti-parallel to the inverter 162. An output of the NAND circuit 152 is input to the transmission gate 161. A clock CK and an inverted clock CKB are input to the transmission gate 161 and the clocked inverter 163 as transition inputs.

The latch circuit 141 includes a transmission gate 171, a NAND circuit 172, and a clocked inverter 173. A reset signal RS is input to a first input terminal of the NAND circuit 172, and the transmission gate 171 is connected to a second input terminal of the NAND circuit 172. The clocked inverter 173 is connected in anti-parallel to the NAND circuit 172. An output of the inverter 162 is input to the transmission gate 171. A clock CK and an inverted clock CKB are input to the transmission gate 171 and the clocked inverter 173 as transition inputs.

The latch circuit 142 includes a transmission gate 181, an inverter 182, and a clocked inverter 183. The transmission gate 181 is connected to an input terminal of the inverter 182. The clocked inverter 183 is connected in anti-parallel to the inverter 182. An output of the NAND circuit 172 is input to the transmission gate 181. An output of the inverter 182 is input to the inverter 291. A clock CK and an inverted clock CKB are input to the transmission gate 181 and the clocked inverter 183 as transition inputs.

The clock CK and the inverted clock CKB input to each of the latch circuits 131 and 141 and the clock CK and the inverted clock CKB input to each of the latch circuits 132 and 142 have phases opposite to each other.

Note that the transmission gates 151, 161, 171, and 181 are examples of a switch circuit described in the claims. The NAND circuits 152 and 172 and the inverters 162 and 182 are examples of a first inverter circuit described in the claims. The clocked inverters 153, 163, 173, and 183 are examples of a second inverter circuit described in the claims.

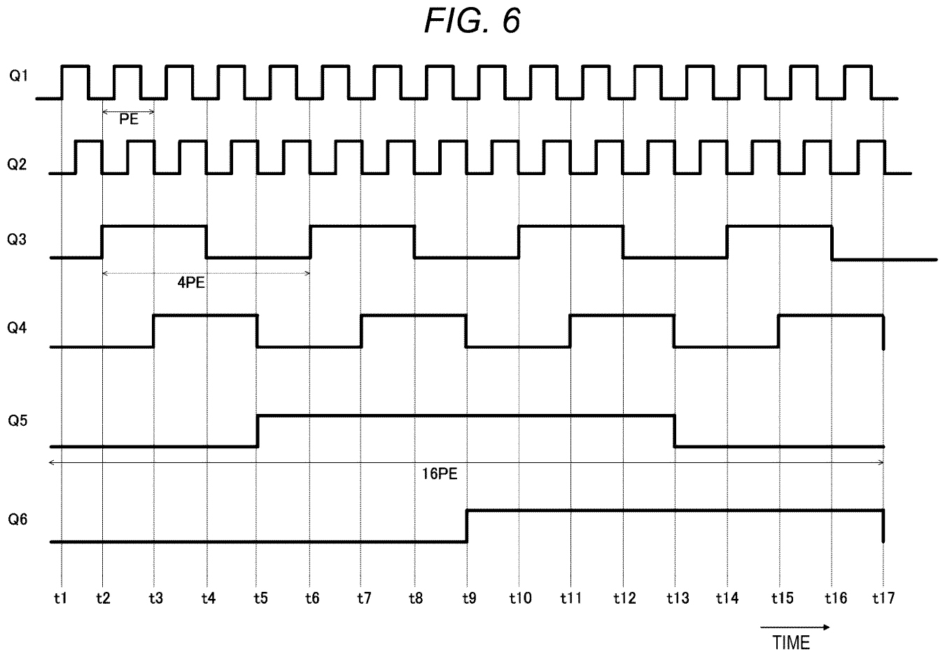

FIG. 6 is a timing chart illustrating an output operation of the counter circuit according to the first embodiment. Note that the drawing illustrates an example in which the pulses PL are periodically input to the counter circuit 124 at ¼ of a period PE of the count value Q2.

In the drawing, the pulses PL are periodically input to the 2-bit Johnson counter 201 as the transition input S at ¼ of the period PE, and the count values Q1 and Q2 are periodically output from the 2-bit Johnson counter 201 at the period PE. At this time, the count values Q1 and Q2 are output with phases shifted from each other by ¼ of the period PE.

The count value Q2 of the 2-bit Johnson counter 201 is periodically input to the 2-bit Johnson counter 202 as the transition input S at the period PE, and the count values Q3 and Q4 are periodically output from the 2-bit Johnson counter 202 at a period 4PE. At this time, the count values Q3 and Q4 are output with phases shifted from each other by the period PE.

The count value Q4 of the 2-bit Johnson counter 202 is periodically input to the 2-bit Johnson counter 203 as the transition input S at the period 4PE, and the count values Q5 and Q6 are periodically output from the 2-bit Johnson counter 203 at a period 16PE. At this time, the count values Q5 and Q6 are output with phases shifted from each other by the period 4PE.

As described above, in the above-described first embodiment, the count value Q2 of the second bit of the 2-bit Johnson counter 201 is set as the transition input of the 2-bit Johnson counter 202. In addition, the count value Q4 of the second bit of the 2-bit Johnson counter 202 is set as the transition input of the 2-bit Johnson counter 203. As a result, the transition period of the 2-bit Johnson counter 202 can be set to four times the transition period of the 2-bit Johnson counter 201, and the transition period of the 2-bit Johnson counter 203 can be set to 16 times the transition period of the 2-bit Johnson counter 201. Therefore, the number of state transitions at a time of counting by the counter circuit can be reduced, and power consumption of the counter circuit can be reduced.

In addition, the number of states of a counter in which 2-bit Johnson counters are connected in n stages is given by 2ⁿ. The number of states of a normal (2×n)-bit Johnson counter, on the other hand, is given by 2×n. Therefore, the number of states of a counter in which 2-bit Johnson counters are connected in n stages can be made larger than the number of states of a normal (2×n)-bit Johnson counter.

Modifications of the counter circuit will be described hereinafter. In the following modifications, configuration examples of a first-stage 2-bit Johnson counter used in a counter circuit will be described, but in each modification, the configuration example of the first-stage 2-bit Johnson counter can also be applied to a subsequent-stage 2-bit Johnson counter.

### 2. Second Embodiment

In the first embodiment described above, a second bit of a count output of a 2-bit Johnson counter at a preceding stage is used as a transition input of a 2-bit Johnson counter at a subsequent stage. In this second embodiment, an output of a clocked inverter of a latch circuit at a subsequent stage of a flip-flop at a subsequent stage is fed back to a flip-flop at a preceding stage in a 2-bit Johnson counter used in each of stages of a counter circuit.

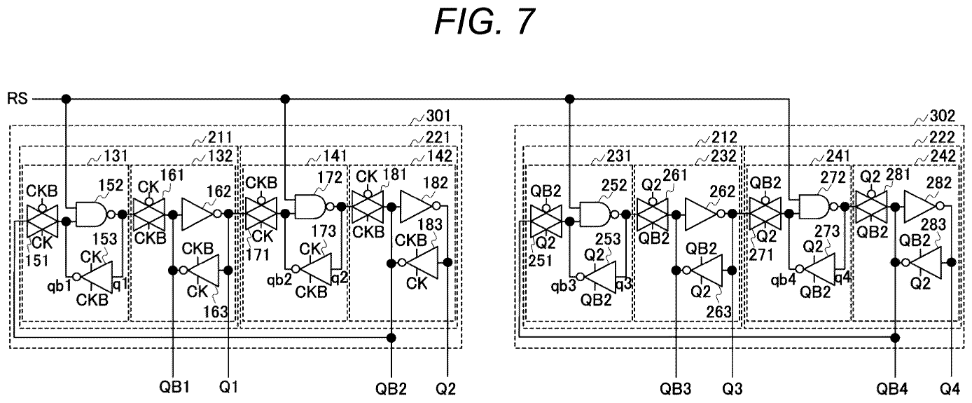

FIG. 7 is a circuit diagram illustrating a configuration example of the counter circuit according to the second embodiment. Note that although the drawing illustrates a counter circuit in which 2-bit Johnson counters are connected in two stages, a counter circuit may be configured by connecting 2-bit Johnson counters in n stages, instead.

In the drawing, the counter circuit includes 2-bit Johnson counters 301 and 302. The 2-bit Johnson counter 302 is connected at a subsequent stage of the 2-bit Johnson counter 301.

The inverter 291 of the 2-bit Johnson counter 201 in the first embodiment described above is removed from the 2-bit Johnson counter 301. Other configurations of the 2-bit Johnson counter 301 are similar to those of the 2-bit Johnson counter 201 in the first embodiment described above.

Here, an inverted count value QB2 of the 2-bit Johnson counter 301 is input to the transmission gate 151. The inverted count value QB2 of the 2-bit Johnson counter 301 is output from the clocked inverter 183. At this time, in the 2-bit Johnson counter 301, a value (inverted count value QB2 held in the flip-flop 221 at the subsequent stage as an inverted value of an output of the flip-flop 221 at the subsequent stage is used as an input of the flip-flop 211 at the preceding stage. In addition, in the 2-bit Johnson counter 302, a value (inverted count value QB4 held in a flip-flop 222 at a subsequent stage as an inverted value of an output of the flip-flop 222 at the subsequent stage is used as an input of a flip-flop 212 at a preceding stage.

The 2-bit Johnson counter 302 includes the flip-flops 212 and 222. The flip-flop 212 includes latch circuits 231 and 232. The latch circuit 232 is connected at a subsequent stage of the latch circuit 231. The flip-flop 222 includes latch circuits 241 and 242. The latch circuit 242 is connected at a subsequent stage of the latch circuit 241.

The latch circuit 231 includes a transmission gate 251, a NAND circuit 252, and a clocked inverter 253. A reset signal RS is input to a first input terminal of the NAND circuit 252, and the transmission gate 251 is connected to a second input terminal of the NAND circuit 252. The clocked inverter 253 is connected in anti-parallel to the NAND circuit 252. The count value Q4 is input to the transmission gate 251 via the inverter 283. A count value Q2 and an inverted count value QB2 are input to the transmission gate 251 and the clocked inverter 253 as transition inputs. The count value Q2 and the inverted count value QB2 have phases opposite to each other.

The latch circuit 232 includes a transmission gate 261, an inverter 262, and a clocked inverter 263. The transmission gate 261 is connected to an input terminal of the inverter 262. The clocked inverter 263 is connected in anti-parallel to the inverter 262. An output of the NAND circuit 252 is input to the transmission gate 261. A count value Q2 and an inverted count value QB2 are input to the transmission gate 261 and the clocked inverter 263 as transition inputs.

The latch circuit 241 includes a transmission gate 271, a NAND circuit 272, and a clocked inverter 273. A reset signal RS is input to a first input terminal of the NAND circuit 272, and the transmission gate 271 is connected to a second input terminal of the NAND circuit 272. The clocked inverter 273 is connected in anti-parallel to the NAND circuit 272. An output of the inverter 262 is input to the transmission gate 271. A count value Q2 and an inverted count value QB2 are input to the transmission gate 271 and the clocked inverter 273 as transition inputs.

The latch circuit 242 includes a transmission gate 281, an inverter 282, and a clocked inverter 283. The transmission gate 281 is connected to an input terminal of the inverter 282. The clocked inverter 283 is connected in anti-parallel to the inverter 282. An output of the NAND circuit 272 is input to the transmission gate 281. An output of the inverter 282 is input to the clocked inverter 283. A count value Q2 and an inverted count value QB2 are input to the transmission gate 281 and the clocked inverter 283 as transition inputs.

The count value Q2 and the inverted count value QB2 input to each of the latch circuits 231 and 241 and the count value Q2 and the inverted count value QB2 input to each of the latch circuits 232 and 242 have phases opposite to each other.

This counter circuit is reset on the basis of the reset signal RS. Here, when the counter circuit performs the counting operation, the reset signal RS is set to a high level. At this time, each of the NAND circuits 152, 172, 252, and 272 operates as an inverter.

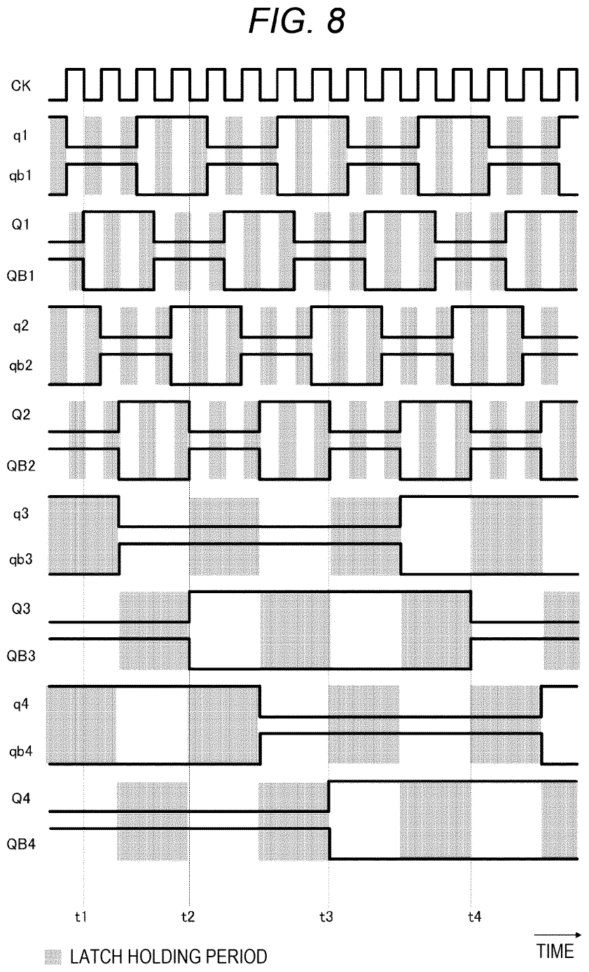

FIG. 8 is a timing chart illustrating an internal state and an output operation of the counter circuit according to the second embodiment. Note that q1 to q4 indicate state values of outputs of the latch circuits 131, 141, 231, and 241, respectively. qb1 to qb4 are inverted state values obtained by inverting the state values q1 to q4.

In the drawing, in the 2-bit Johnson counter 301, the transmission gates 151, 161, 171, and 181 and the clocked inverters 153, 163, 173, and 183 open and close in accordance with the clock CK. At this time, when the transmission gates 151 and 171 and the clocked inverters 163 and 183 are closed, the transmission gates 161 and 181 and the clocked inverters 153 and 173 are opened. When the transmission gates 161 and 181 and the clocked inverters 153 and 173 are closed, the transmission gates 151 and 171 and the clocked inverters 163 and 183 are opened.

Here, it is assumed that the transmission gates 151 and 171 and the clocked inverters 163 and 183 are closed, and the transmission gates 161 and 181 and the clocked inverters 153 and 173 are opened. At this time, data is input to the latch circuits 131 and 141 in a state where the data is latched and held in the latch circuits 132 and 142.

Next, it is assumed that the transmission gates 161 and 181 and the clocked inverters 153 and 173 are closed, and the transmission gates 151 and 171 and the clocked inverters 163 and 183 are opened. At this time, data is input to the latch circuits 132 and 142 in a state where the data is latched and held in the latch circuits 131 and 141.

As described above, in the 2-bit Johnson counter 301, the count value Q1 transitions on the basis of the state value q1, the state value q2 transitions on the basis of the count value Q1, and the count value Q2 transitions on the basis of the state value q2 in accordance with the period of the clock signal CK. Furthermore, the count value Q2 is fed back to the input of the 2-bit Johnson counter 301 via the clocked inverter 183, and the state value q1 transitions on the basis of the count value Q2. As a result, the 2-bit Johnson counter 301 can perform a counting operation for 2 bits in accordance with the period of the clock signal CK.

In the 2-bit Johnson counter 302, the transmission gates 251, 261, 271, and 281 and the clocked inverters 253, 263, 273, and 283 open and close in accordance with the count value Q2. At this time, when the transmission gates 251 and 271 and the clocked inverters 263 and 283 are closed, the transmission gates 261 and 281 and the clocked inverters 253 and 273 are opened. When the transmission gates 261 and 281 and the clocked inverters 253 and 273 are closed, the transmission gates 251 and 271 and the clocked inverters 263 and 283 are opened.

Here, when the transmission gates 251 and 271 and the clocked inverters 263 and 283 are closed, the transmission gates 261 and 281 and the clocked inverters 253 and 273 are opened. At this time, data is input to the latch circuits 231 and 241 in a state where the data is latched and held in the latch circuits 232 and 242.

Next, it is assumed that the transmission gates 261 and 281 and the clocked inverters 253 and 273 are closed, and the transmission gates 251 and 271 and the clocked inverters 263 and 283 are opened. At this time, data is input to the latch circuits 232 and 242 in a state where the data is latched and held in the latch circuits 231 and 241.

As described above, in the 2-bit Johnson counter 302, the count value Q3 transitions on the basis of the state value q3, the state value q4 transitions on the basis of the count value Q3, and the count value Q4 transitions on the basis of the state value q4 in accordance with the period of the count value Q2. Furthermore, the count value Q4 is fed back to the input of the 2-bit Johnson counter 302 via the clocked inverter 283, and the state value q3 transitions on the basis of the count value Q4. As a result, the 2-bit Johnson counter 302 can perform a counting operation for 2 bits higher than those of the 2-bit Johnson counter 301 in accordance with the period of the count value Q2.

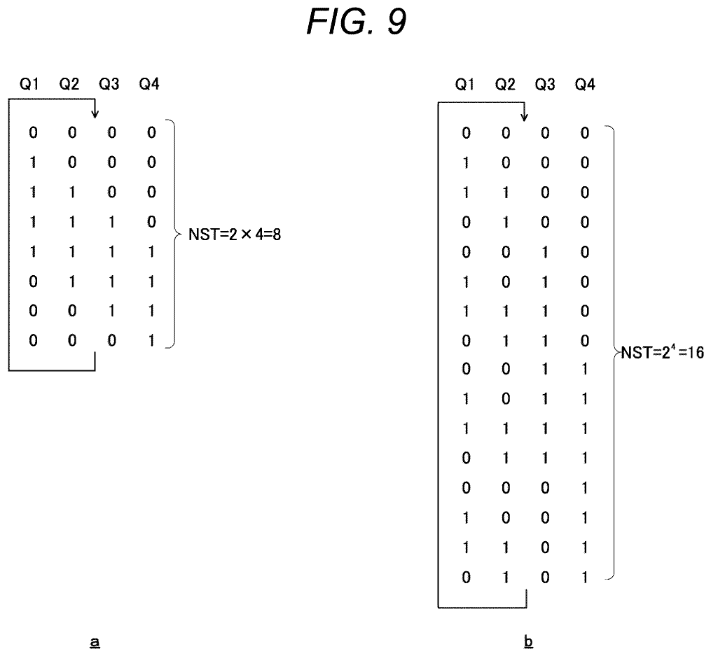

FIG. 9 is a diagram illustrating comparison of state transitions of the counter circuit according to the second embodiment with those in a comparative example. Note that, in the drawing, state transitions of a 4-bit counter are taken as an example.

In a of the drawing, the number of states NST of the normal 4-bit Johnson counter is 2×4=8. In b of the drawing, on the other hand, the number of states NST of a counter in which 2-bit Johnson counters are connected in two stages is 2⁴=16. Therefore, the number of states of the counter in which 2-bit Johnson counters are connected in two stages can be made larger than the number of states of a normal 4-bit Johnson counter.

As described above, in the above-described second embodiment, the 2-bit Johnson counter 301 feeds back the output of the clocked inverter 183, and the 2-bit Johnson counter 302 feeds back the output of the clocked inverter 283. As a result, the inverters 291 and 292 in the first embodiment described above can be made unnecessary, and circuit area can be reduced.

### 3. Third Embodiment

In the second embodiment described above, the transmission gate 151 is provided at the input of the latch circuit 131 of the 2-bit Johnson counter 301. In a third embodiment, a clocked inverter is provided at an input of a latch circuit at a first stage of a 2-bit Johnson counter.

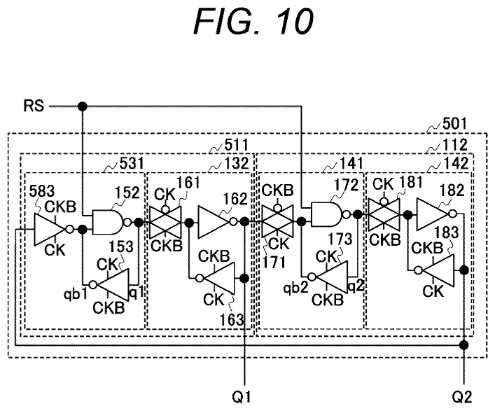

FIG. 10 is a circuit diagram illustrating a configuration example of a counter circuit according to the third embodiment.

In the drawing, this 2-bit Johnson counter 501 includes a flip-flop 511 instead of the flip-flop 211 of the 2-bit Johnson counter 301 in the second embodiment described above. The flip-flop 511 includes a latch circuit 531 instead of the latch circuit 131 in the second embodiment. The latch circuit 132 is connected at a subsequent stage of the latch circuit 531.

The latch circuit 531 includes a clocked inverter 583 instead of the transmission gate 151 in the second embodiment described above. A count value Q2 of the 2-bit Johnson counter 501 is input to a second input terminal of the NAND circuit 152 via the clocked inverter 583. Other configurations of the 2-bit Johnson counter 501 in the third embodiment are similar to those of the 2-bit Johnson counter 301 in the second embodiment described above.

As described above, in the third embodiment described above, the clocked inverter 583 is provided at the input of the latch circuit 531 at the first stage of the 2-bit Johnson counter 501. As a result, data can be prevented from being rewritten via a feedback path input to the clocked inverter 583, and stability of the operation of the count circuit can be improved.

### 4. Fourth Embodiment

In the second embodiment described above, the output of the clocked inverter 183 is fed back to the input of the latch circuit 131 in the 2-bit Johnson counter 301. In this fourth embodiment, a capacitor is connected to a feedback path of a 2-bit Johnson counter.

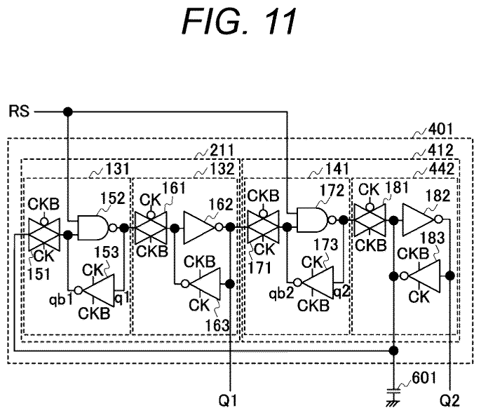

FIG. 11 is a circuit diagram illustrating a first example of a counter circuit according to the fourth embodiment.

In the drawing, in this counter circuit, a capacitor 601 is added to the counter circuit in the second embodiment described above. The capacitor 601 is connected to a feedback path input to the transmission gate 151. The capacitor 601 may be a metal capacitor in which a dielectric layer is sandwiched between metal layers. Other configurations of the counter circuit in the fourth embodiment are similar to those of the counter circuit in the second embodiment described above.

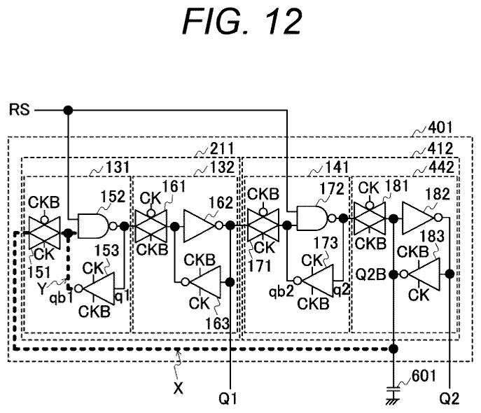

FIG. 12 is a circuit diagram illustrating an example of the capacitor in the feedback path of the counter circuit according to the fourth embodiment.

In the figure, the foodback path of the counter circuit is provided from the output of the clocked inverter 183 to the input of the transmission gate 151. At this time, a capacitor X is added to the foodback path. In addition, a capacitor Y is added to the output of the transmission gate 151.

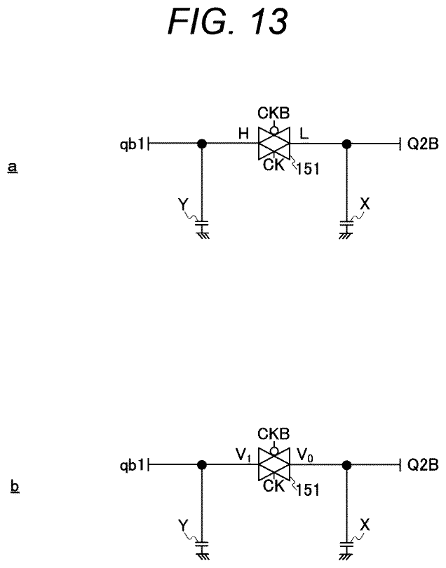

FIG. 13 is a circuit diagram illustrating an example of a change in a potential in the feedback path of the counter circuit according to the fourth embodiment.

In a of the drawing, the capacitor X is equivalently added to an input side of the transmission gate 151, and the capacitor Y is equivalently added to an output side of the transmission gate 151. At this time, when the transmission gate 151 is off, the input side of the transmission gate 151 is at a low level, and the output side of the transmission gate 151 is at a high level.

Here, as illustrated in b of the drawing, a potential on the input side of the transmission gate 151 when the transmission gate 151 is short-circuited due to a phase shift of the clock signal CK is V₀. At this time, assuming that a potential on the output side of the transmission gate 151 is V₁, the following relational expression is established for the potential V₀ and the capacitors X and Y.

$$Y \cdot {V}_{1} = X \cdot {V}_{0} + Y \cdot {V}_{0}$$

Therefore, the potential V₀ is given by the following formula.

$${V}_{0} = {V}_{1} / ( 1 + X / Y )$$

By setting a capacitance value of the capacitor 601 in such a way as to satisfy a relationship of X>Y from the above equation, the potential V₀ on the input side of the transmission gate 151 can be stabilized.

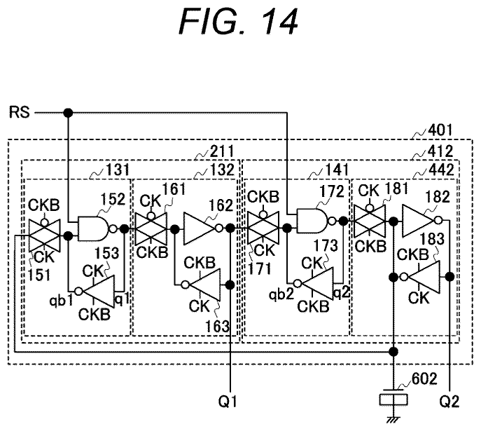

FIG. 14 is a circuit diagram illustrating a second example of the counter circuit according to the fourth embodiment.

In the drawing, in this counter circuit, a gate capacitor 602 is used as the capacitor 601 of the first example of the counter circuit in the fourth embodiment described above. Other configurations of the second example of the counter circuit in the fourth embodiment are similar to those of the first example of the counter circuit in the fourth embodiment described above.

The gate capacitor 602 may be implemented as a MOS transistor. At this time, a gate of the MOS transistor may be connected to the input side of the transmission gate 151. A source potential, a drain potential, and a substrate potential of the MOS transistor may be set to a ground potential.

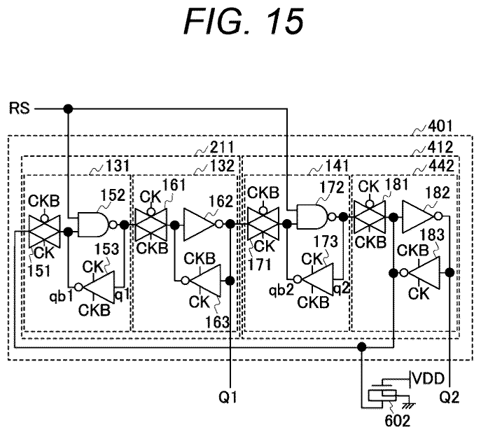

FIG. 15 is a circuit diagram illustrating a third example of the counter circuit according to the fourth embodiment.

In the drawing, in this counter circuit, a gate capacitor 602 is used as the capacitor 601 of the first example of the counter circuit in the fourth embodiment described above. Other configurations of the third example of the counter circuit in the fourth embodiment are similar to those of the first example of the counter circuit in the fourth embodiment described above.

The gate capacitor 602 may be implemented as a MOS transistor. At this time, a source and a drain of the MOS transistor may be connected to the input side of the transmission gate 151. A gate potential of the MOS transistor may be set to a power supply potential VDD. A substrate potential of the MOS transistor may be set to the ground potential. As a result, capacitance of the gate capacitor 602 when the foodback path of the counter circuit is at the low level can be increased.

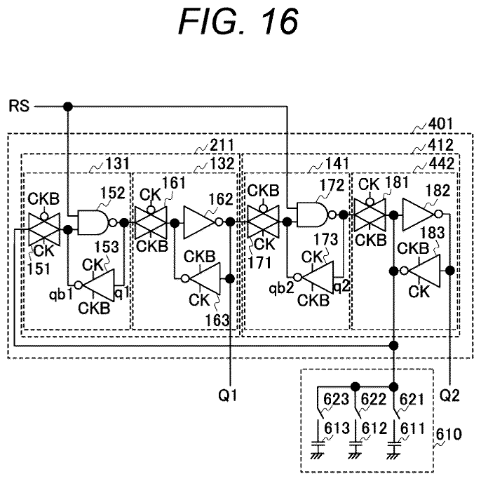

FIG. 16 is a circuit diagram illustrating a fourth example of the counter circuit according to the fourth embodiment.

In the drawing, in this counter circuit, a variable capacitor 610 is used instead of the capacitor 601 of the first example of the counter circuit in the fourth embodiment described above. Other configurations of the fourth example of the counter circuit in the fourth embodiment are similar to those of the first example of the counter circuit in the fourth embodiment described above.

The variable capacitor 610 includes a plurality of capacitors 611 to 613. Switches 621 to 623 are connected in series to the capacitors 611 to 613, respectively. The series circuits of the capacitors 611 to 613 and the switches 621 to 623 may be connected in parallel to one another on the input side of the transmission gate 151. Each of the capacitors 611 to 613 may be a metal capacitor or a gate capacitor. At this time, a capacitance value of the variable capacitor 610 can be changed by changing the number of the switches 621 to 623 in an on state. Here, by changing the capacitance value of the variable capacitor 610, it is possible to perform defect acceleration verification, by which a defect rate can be estimated through extrapolation on the basis of a relationship between capacitance and the defect rate. In the defect acceleration verification, it is possible to improve the stability of the counter circuit while optimizing the capacitance value of the variable capacitor 610 and suppressing a decrease in operation speed of the counter circuit.

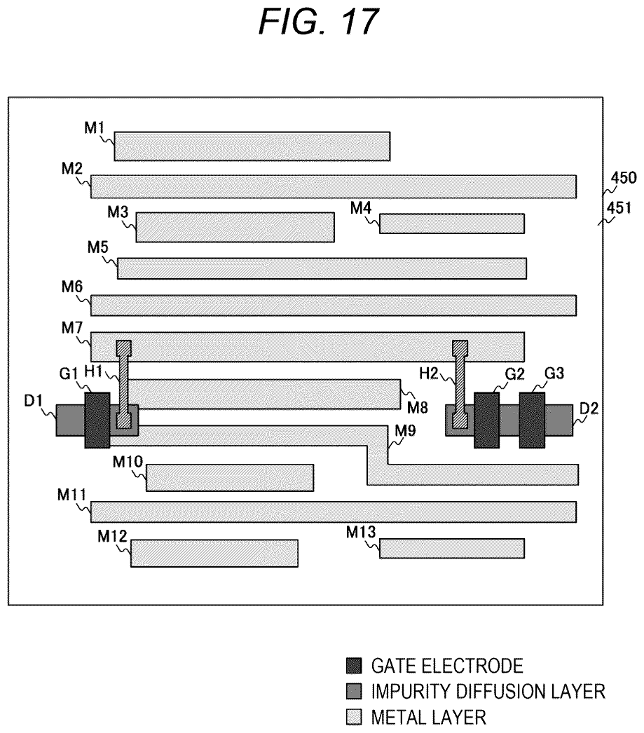

FIG. 17 is a plan view illustrating a layout example of the counter circuit according to the fourth embodiment. Note that, in the drawing, a layout example of the transmission gate 151, the clocked inverter 183, the capacitor 601, and wirings connected thereto is illustrated.

In the drawing, impurity diffusion layers D1 and D2 are formed on a semiconductor substrate 450. The impurity diffusion layers D1 and D2 are device-isolated from each other via a device isolation layer 451.

On the semiconductor substrate 450, a gate electrode G1 is provided in such a way as to separate the impurity diffusion layer D1. At this time, the transmission gate 151 is formed. In addition, on the semiconductor substrate 450, gate electrodes G2 and G3 are provided in such a way as to separate the impurity diffusion layer D2. At this time, the clocked inverter 183 is formed.

In addition, metal layers M1 to M13 are formed on the semiconductor substrate 450. The metal layers M1 and M12 can be used to input the clock signal CK. The metal layers M2 and M6 can be used to supply a power supply voltage. The metal layer M11 can be used to supply the ground potential. The metal layer M3 can be used as output wiring of the transmission gate 151. The metal layer M4 can be used as output wiring of the transmission gate 161. The metal layer M5 can be used to input the reset signal RS. The metal layer M7 can be used as input wiring of the transmission gate 151. When widths of the metal layers M3 and M7 are made equal to each other at this time, length of the metal layer M7 can be made greater than length of the metal layer M3. As a result, the capacitor 601 can be added to the feedback path in such a way as to satisfy the relationship of X>Y. The metal layer M8 can be used to input the inverted clock CKB. The metal layer M9 can be used as output wiring of the inverter 162. The metal layer M10 can be used as output wiring of the clocked inverter 173. The metal layer M13 can be used as output wiring of the inverter 182. A material of the metal layers M1 to M13 and the wiring layers H1 and H2 may be Al or Cu.

As described above, in the fourth embodiment described above, the capacitor 601 is connected to the feedback path of the 2-bit Johnson counter 401. As a result, data can be prevented from being rewritten via the feedback path input to the transmission gate 151, and the stability of the operation of the count circuit can be improved.

### 5. Fifth Embodiment

In the second embodiment described above, the clocked inverter 183 is provided for the latch circuit 142 of the 2-bit Johnson counter 301, and the clocked inverter 183 is connected in anti-parallel to the inverter 182. In this fifth embodiment, a series circuit of a transmission gate and an inverter is provided for a latch circuit at a subsequent stage of a flip-flop at a subsequent stage of a 2-bit Johnson counter, and the series circuit is connected in anti-parallel to the inverter 182.

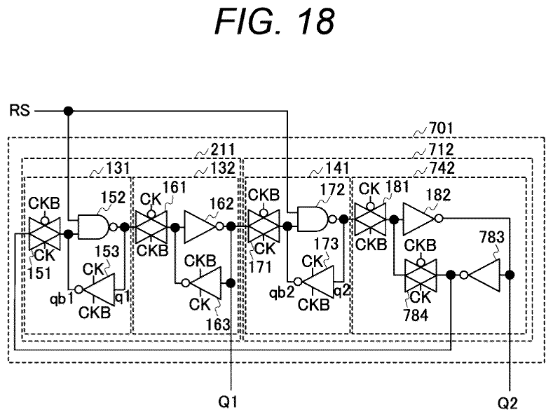

FIG. 18 is a circuit diagram illustrating a configuration example of a counter circuit according to the fifth embodiment.

In the drawing, this 2-bit Johnson counter 701 includes a flip-flop 712 instead of the flip-flop 221 of the 2-bit Johnson counter 301 in the second embodiment described above. The flip-flop 712 includes a latch circuit 742 instead of the latch circuit 142 in the second embodiment described above. The latch circuit 742 is connected at a subsequent stage of the latch circuit 141.

The latch circuit 742 includes an inverter 783 and a transmission gate 784 instead of the clocked inverter 183 in the second embodiment described above. An output of the inverter 783 is connected to an input of the transmission gate 784. A series circuit of the inverter 783 and the transmission gate 784 is connected in anti-parallel to the inverter 182. Other configurations of the 2-bit Johnson counter 701 in the fifth embodiment are similar to those of the 2-bit Johnson counter 301 in the second embodiment described above.

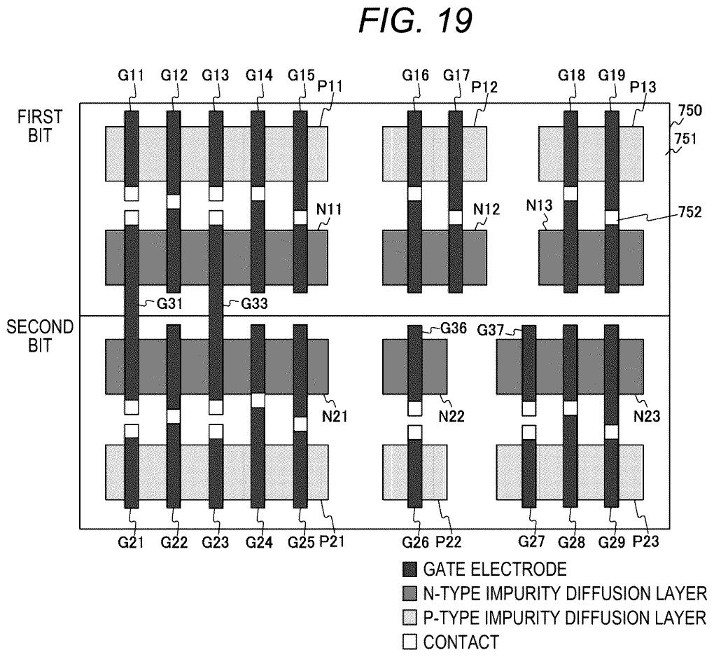

FIG. 19 is a plan view illustrating a layout example of the 2-bit Johnson counter according to the fifth embodiment.

In the drawing, in the semiconductor substrate 750, P-type impurity diffusion layers P11 to P13 and P21 to P23 and N-type impurity diffusion layers N11 to N13 and N21 to N23 are formed. The P-type impurity diffusion layers P11 to P13 and the N-type impurity diffusion layers N11 to N13 are arranged symmetrically to each other. The P-type impurity diffusion layers P21 to P23 and the N-type impurity diffusion layers N21 to N23 are arranged symmetrically to each other. The P-type impurity diffusion layers P11 to P13 and P21 to P23 and the N-type impurity diffusion layers N11 to N13 and N21 to N23 are device-isolated from each other via a device isolation layer 751.

On the semiconductor substrate 750, a gate electrode G11 is provided in such a way as to separate the P-type impurity diffusion layer P11, a gate electrode G21 is provided in such a way as to separate the P-type impurity diffusion layer P21, and a gate electrode G31 is provided in such a way as to separate the N-type impurity diffusion layers N11 and N21. At this time, the transmission gates 151 and 171 are formed.

On the semiconductor substrate 750, a gate electrode G12 is provided in such a way as to separate the P-type impurity diffusion layer P11 and the N-type impurity diffusion layer N11, and a gate electrode G13 is provided in such a way as to separate the P-type impurity diffusion layer P11. In addition, on the semiconductor substrate 750, a gate electrode G22 is provided in such a way as to separate the P-type impurity diffusion layer P21 and the N-type impurity diffusion layer N21, and a gate electrode G23 is provided in such a way as to separate the P-type impurity diffusion layer P21. In addition, on the semiconductor substrate 750, a gate electrode G33 is provided in such a way as to separate the N-type impurity diffusion layers N11 and N21. At this time, the clocked inverters 153 and 173 are formed.

On the semiconductor substrate 750, gate electrodes G14 and G15 are provided in such a way as to separate the P-type impurity diffusion layer P11 and the N-type impurity diffusion layer N11. At this time, the NAND circuit 172 is formed.

On the semiconductor substrate 750, gate electrodes G24 and G25 are provided in such a way as to separate the P-type impurity diffusion layer P21 and the N-type impurity diffusion layer N21. At this time, the NAND circuit 152 is formed.

On the semiconductor substrate 750, a gate electrode G16 is provided in such a way as to separate the P-type impurity diffusion layer P12 and the N-type impurity diffusion layer N12. At this time, the transmission gate 181 is formed.

On the semiconductor substrate 750, a gate electrode G17 is provided in such a way as to separate the P-type impurity diffusion layer P12 and the N-type impurity diffusion layer N12. At this time, the transmission gate 784 is formed.

On the semiconductor substrate 750, a gate electrode G26 is provided in such a way as to separate the P-type impurity diffusion layer P22, and a gate electrode G36 is provided in such a way as to separate the N-type impurity diffusion layer N22. At this time, the transmission gate 161 is formed.

On the semiconductor substrate 750, a gate electrode G18 is provided in such a way as to separate the P-type impurity diffusion layer P13 and the N-type impurity diffusion layer N13. At this time, the inverter 783 is formed.

On the semiconductor substrate 750, a gate electrode G19 is provided in such a way as to separate the P-type impurity diffusion layer P13 and the N-type impurity diffusion layer N13. At this time, the inverter 182 is formed.

On the semiconductor substrate 750, a gate electrode G27 is provided in such a way as to separate the P-type impurity diffusion layer P23, a gate electrode G37 is provided in such a way as to separate the N-type impurity diffusion layer N23, and a gate electrode G28 is provided in such a way as to separate the N-type impurity diffusion layer N23 and the P-type impurity diffusion layer P23. At this time, the clocked inverter 163 is formed.

On the semiconductor substrate 750, a gate electrode G29 is provided in such a way as to separate the N-type impurity diffusion layer N23 and the P-type impurity diffusion layer P23. At this time, the inverter 162 is formed.

Here, a channel region is formed under each of the gate electrodes G11 to G19, G21 to G29, G33, G36, and G37. In addition, a contact 752 is formed in each of the gate electrodes G11 to G19, G21 to G29, G31, G33, G36, and G37.

A material of the semiconductor substrate 750 may be Si, InGaAs, or InP. A material of the device isolation layer 751 may be SiO₂. A material of each of the gate electrodes G11 to G19, G21 to G29, G31, G33, G36, and G37 may be polycrystalline silicon.

As described above, in the fifth embodiment described above, the series circuit of the transmission gate 784 and the inverter 783 is provided for the latch circuit 742 of the 2-bit Johnson counter 701, and the series circuit is connected in anti-parallel to the inverter 182. As a result, the count value Q2 of the 2-bit Johnson counter 701 can be fed back to the input of the transmission gate 151 via the inverter 783, and the stability of the operation of the count circuit can be improved. In addition, the inverter 291 in the first embodiment described above can be made unnecessary, and circuit area can be reduced.

### 6. Sixth Embodiment

In the fifth embodiment described above, the series circuit of the transmission gate 784 and the inverter 783 is provided for the latch circuit 742 of the 2-bit Johnson counter 701, and the series circuit is connected in anti-parallel to the inverter 182. In this sixth embodiment, in a 2-bit Johnson counter, a series circuit of a transmission gate and an inverter is provided for a latch circuit at a subsequent stage of a flip-flop at a preceding stage and a latch circuit at a subsequent stage of a flip-flop at a subsequent stage.

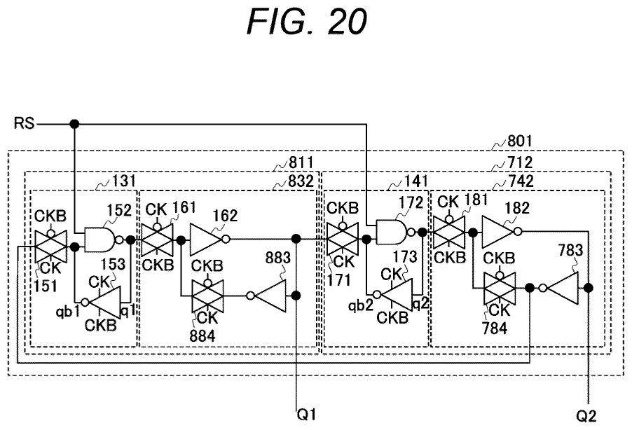

FIG. 20 is a circuit diagram illustrating a configuration example of a counter circuit according to the sixth embodiment.

In the drawing, this 2-bit Johnson counter 801 includes a flip-flop 811 instead of the flip-flop 211 of the 2-bit Johnson counter 701 in the fifth embodiment described above. The flip-flop 811 includes a latch circuit 832 instead of the latch circuit 132 in the fifth embodiment described above. The latch circuit 832 is connected at a subsequent stage of the latch circuit 131.

The latch circuit 832 includes an inverter 883 and a transmission gate 884 instead of the clocked inverter 163 in the fifth embodiment described above. An output of the inverter 883 is connected to an input of the transmission gate 884. A series circuit of the inverter 883 and the transmission gate 884 is connected in anti-parallel to the inverter 162. Other configurations of the 2-bit Johnson counter 801 in the sixth embodiment are similar to those of the 2-bit Johnson counter 701 in the fifth embodiment described above.

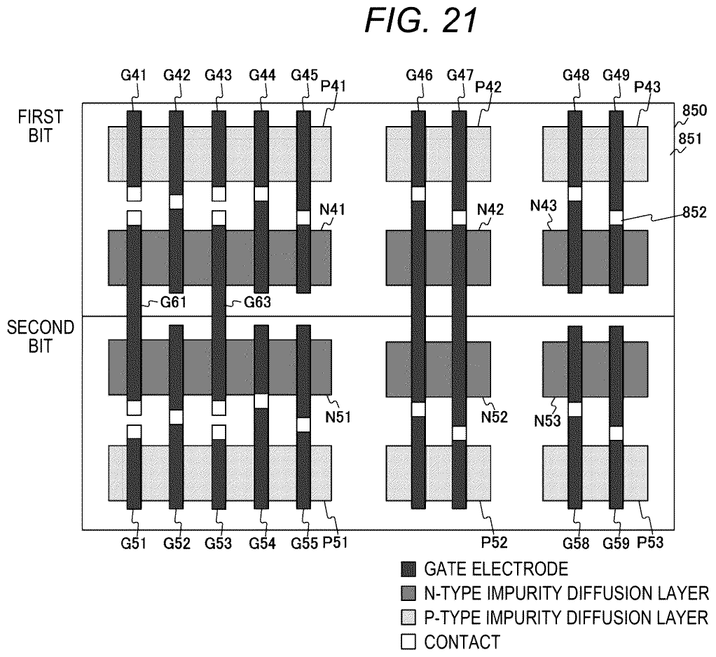

FIG. 21 is a plan view illustrating a layout example of the 2-bit Johnson counter according to the sixth embodiment.

In the drawing, in the semiconductor substrate 850, P-type impurity diffusion layers P41 to P43 and P51 to P53 and N-type impurity diffusion layers N41 to N43 and N51 to N53 are formed. The P-type impurity diffusion layers P41 to P43 and the N-type impurity diffusion layers N41 to N43 are arranged symmetrically to each other. The P-type impurity diffusion layers P51 to P53 and the N-type impurity diffusion layers N51 to N53 are arranged symmetrically to each other. The P-type impurity diffusion layers P41 to P43 and the P-type impurity diffusion layers P51 to P53 are arranged symmetrically to each other. The N-type impurity diffusion layers N41 to N43 and the N-type impurity diffusion layers N51 to N53 are arranged symmetrically to each other. The P-type impurity diffusion layers P41 to P43 and P51 to P53 and the N-type impurity diffusion layers N41 to N43 and N51 to N53 are device-isolated from each other via a device isolation layer 851.

On the semiconductor substrate 850, a gate electrode G41 is provided in such a way as to separate the P-type impurity diffusion layer P41, a gate electrode G51 is provided in such a way as to separate the P-type impurity diffusion layer P51, and a gate electrode G61 is provided in such a way as to separate the N-type impurity diffusion layers N41 and N51. At this time, the transmission gates 151 and 171 are formed.

On the semiconductor substrate 850, a gate electrode G42 is provided in such a way as to separate the P-type impurity diffusion layer P41 and the N-type impurity diffusion layer N41, a gate electrode G43 is provided in such a way as to separate the P-type impurity diffusion layer P41, and a gate electrode G52 is provided in such a way as to separate the P-type impurity diffusion layer P51 and the N-type impurity diffusion layer N51. In addition, a gate electrode G53 is provided in such a way as to separate the P-type impurity diffusion layer P51, and a gate electrode G63 is provided in such a way as to separate the N-type impurity diffusion layers N41 and N51. At this time, the clocked inverters 153 and 173 are formed.

On the semiconductor substrate 850, gate electrodes G44 and G45 are provided in such a way as to separate the P-type impurity diffusion layer P41 and the N-type impurity diffusion layer N41. At this time, the NAND circuit 172 is formed.

On the semiconductor substrate 850, gate electrodes G54 and G55 are provided in such a way as to separate the P-type impurity diffusion layer P51 and the N-type impurity diffusion layer N51. At this time, the NAND circuit 152 is formed.

On the semiconductor substrate 850, gate electrodes G46 and G47 are provided in such a way as to separate the P-type impurity diffusion layers P42 and P52 and the N-type impurity diffusion layers N42 and N52. At this time, the transmission gates 161, 181, 784, and 884 are formed.

On the semiconductor substrate 850, a gate electrode G48 is provided in such a way as to separate the P-type impurity diffusion layer P43 and the N-type impurity diffusion layer N43. At this time, the inverter 783 is formed.

On the semiconductor substrate 850, a gate electrode G49 is provided in such a way as to separate the P-type impurity diffusion layer P43 and the N-type impurity diffusion layer N43. At this time, the inverter 182 is formed.

On the semiconductor substrate 850, a gate electrode G58 is provided in such a way as to separate the N-type impurity diffusion layer N53 and the P-type impurity diffusion layer P53. At this time, the inverter 883 is formed.

On the semiconductor substrate 850, a gate electrode G59 is provided in such a way as to separate the N-type impurity diffusion layer N53 and the P-type impurity diffusion layer P53. At this time, the inverter 162 is formed.

Here, a channel region is formed under each of the gate electrodes G41 to G49, G51 to G59, G61, and G63. In addition, a contact 852 is formed in each of the gate electrodes G41 to G49, G51 to G59, G61, and G63.

As described above, in the sixth embodiment described above, the series circuit of the transmission gate 884 and the inverter 883 is provided for the latch circuit 832 of the 2-bit Johnson counter 801, and the series circuit of the transmission gate 784 and the inverter 783 is provided for the latch circuit 742. As a result, configurations of the flip-flop 811 at the preceding stage and the flip-flop 712 at the subsequent stage of the 2-bit Johnson counter 801 can be made equal to each other, and the layout is symmetrical.

### 7. Seventh Embodiment

In the second embodiment described above, the output of the clocked inverter 183 of the latch circuit 142 at the subsequent stage of the flip-flop 221 at the subsequent stage is fed back to the flip-flop 211 at the preceding stage in the 2-bit Johnson counter 301 used in each of stages of the counter circuit. In this seventh embodiment, a value held in each flip-flop as an inverted value of an output of the flip-flop is used as an output of a counter circuit in each of a plurality of 2-bit Johnson counters.

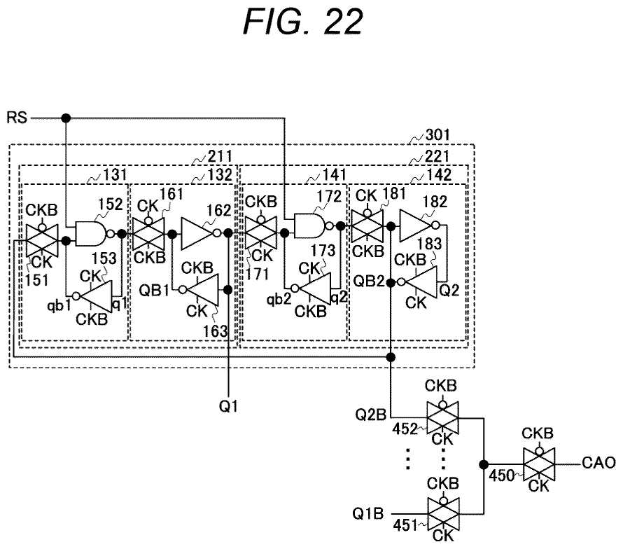

FIG. 22 is a circuit diagram illustrating a configuration example of a counter circuit according to the seventh embodiment.

In the figure, transmission gates 450, 451, and 452 are added to the counter circuit. The transmission gates 451 and 452 can be provided as many as the number of bits of the counter circuit. At this time, an inverted count value corresponding to each bit of the counter circuit is input to each of the transmission gates 451 and 452. For example, in a 2-bit Johnson counter 301, an inverted count value Q1B is input to the transmission gate 451, and an inverted count value Q2B is input to the transmission gate 452.

Outputs of the transmission gates 451 and 452 are connected to the transmission gate 450, and a count value CAO of the counter circuit is output from the transmission gate 450. Other configurations of the counter circuit in the seventh embodiment are similar to those of the counter circuit in the second embodiment described above.

As described above, in the seventh embodiment described above, the value held in each flip-flop as the inverted value of the output of the flip-flop is used as the output of the counter circuit in each of the plurality of 2-bit Johnson counters. As a result, it is possible to output the values held in the counter circuit as count values while forming the 2-bit Johnson counters using the flip-flops connected in two stages.

### 8. Eighth Embodiment

In the first embodiment described above, a second bit of a count output of a 2-bit Johnson counter at a preceding stage is used as a transition input of a 2-bit Johnson counter at a subsequent stage. In this eighth embodiment, a pixel array unit in which pixels provided with light receiving elements are arranged is provided on an upper layer chip, and a circuit array unit in which circuit units including counter circuits configured by connecting 2-bit Johnson counters in n stages are arranged is provided on a lower layer chip.

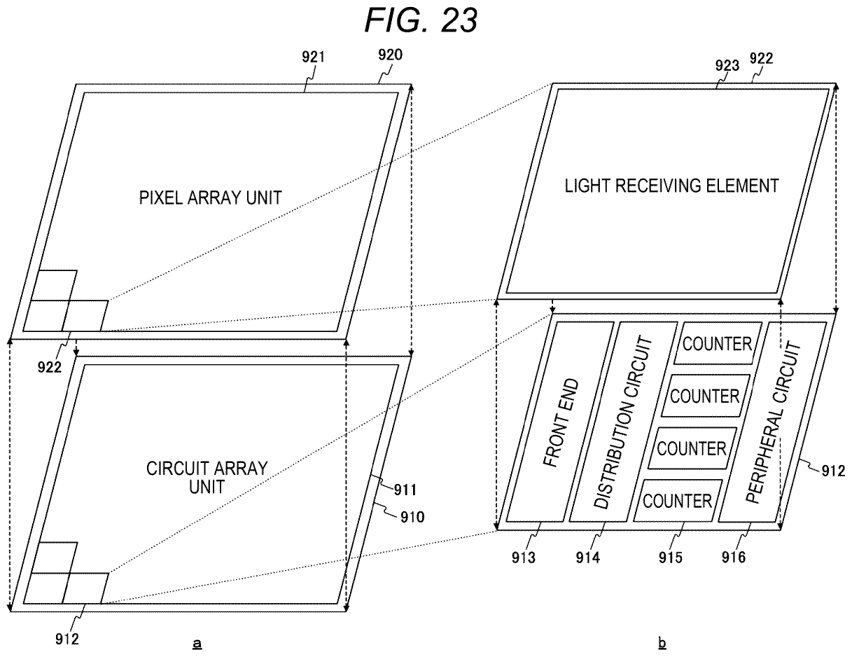

FIG. 23 is a perspective view illustrating a layout example of a solid-state imaging device according to the eighth embodiment. Note that a in the drawing illustrates an overall configuration of the solid-state imaging device. b in the drawing illustrates a pixel 922 and a circuit unit 912 of the solid-state imaging device in an enlarged manner.

In a of the drawing, the solid-state imaging device includes a light receiving chip 920 and a circuit chip 910. The light receiving chip 920 is stacked on the circuit chip 910. The light receiving chip 920 and the circuit chip 910 are electrically connected to each other through a connection units such as vias. For the electrical connection between the light receiving chip 920 and the circuit chip 910, bumps may be used, or direct bonding including Cu—Cu connection may be used.

A pixel array unit 921 is formed on the light receiving chip 920. The pixel array unit 921 is provided with a plurality of pixels 922. The pixels 922 may be arranged in a row direction and a column direction in a maritox. In each pixel 922, as illustrated in b of the drawing, a light receiving element 923 is formed. The light receiving element 923 may be a SPAD or a photodiode.

Furthermore, as illustrated in b of the drawing, a circuit array unit 911 is formed on the circuit chip 910. The circuit array unit 911 is provided with a plurality of circuit units 912. Each circuit unit 912 can be provided for a corresponding one of the pixels 922. The circuit units 912 may be arranged in a row direction and a column direction in a maritox as with the arrangement of the pixels 922.

In each circuit unit 912, as illustrated in b of the drawing, a front end 913, a distribution circuit 914, a plurality of counters 915, and a peripheral circuit 916 are formed. The front end 913 can function as an interface with the light receiving element 923. At this time, the front end 913 can enable quenching or recharging of a SPAD when the SPAD is used as the light receiving element 923. In addition, the front end 913 inputs a signal detected by the light receiving element 923 to the distribution circuit 914. The distribution circuit 914 distributes an output of the pixel 922 to a plurality of paths.

The counters 915 count pulses output from the light receiving element 923. The counters 915 may be provided as many as the number of paths to which the output is distributed by the distribution circuit 914. As the counters 915, any of the counter circuits according to the first to sixth embodiments described above may be used. The peripheral circuit 916 can control the operation of the pixel 922 and control the output of the count values counted by the counters 915.

As described above, in the above-described eighth embodiment, the light receiving chip 920 provided with the light receiving elements 923 and the circuit chip 910 provided with the counters 915 are stacked. As a result, it is possible to increase area of the light receiving elements 923 while suppressing an increase in chip size, and it is possible to improve sensitivity while downsizing the solid-state imaging device.

### 9. Ninth Embodiment

In the above-described eighth embodiment, a solid-state imaging device including counter circuits configured by connecting 2-bit Johnson counters in n stages is formed on one chip. In this ninth embodiment, a solid-state imaging device including counter circuits configured by connecting 2-bit Johnson counters in n stages is formed on one chip.

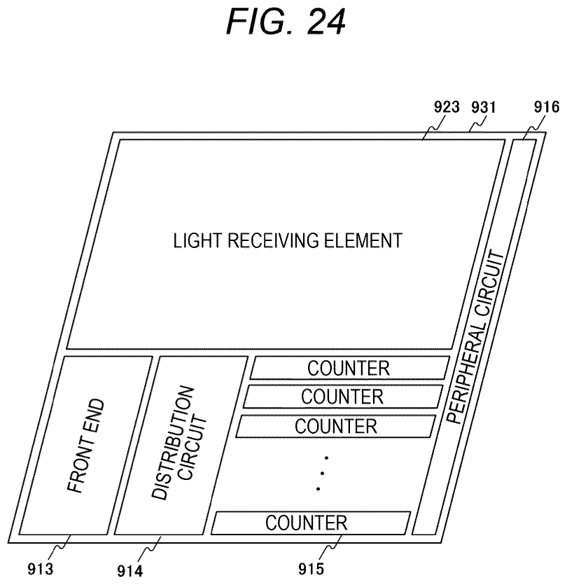

FIG. 24 is a perspective view illustrating a layout example of the solid-state imaging device according to the ninth embodiment.

In the drawing, the solid-state imaging device includes a semiconductor chip 931. On the semiconductor chip 931, a light receiving element 923, a front end 913, a distribution circuit 914, a plurality of counters 915, and a peripheral circuit 916 are formed. At this time, the light receiving element 923, the front end 913, the distribution circuit 914, the plurality of counters 915, and the peripheral circuit 916 are disposed flat.

As described above, in the ninth embodiment described above, the light receiving element 923 and the counters 915 are disposed flat on the semiconductor chip 931. As a result, the semiconductor chip 931 on which the light receiving element 923 and the counters 915 are formed can be cut out from the same wafer, and manufacturing of the solid-state imaging device can be made efficient.

### 10. Tenth Embodiment

In this ninth embodiment, the pixel array unit in which SPADs are provided is provided on the upper layer chip, and the circuit array unit including the counter circuits configured by connecting 2-bit Johnson counters in n stages is provided on the lower layer chip. In this tenth embodiment, a light receiving element of each pixel is provided on an upper layer chip and a circuit unit is provided on a lower layer chip.

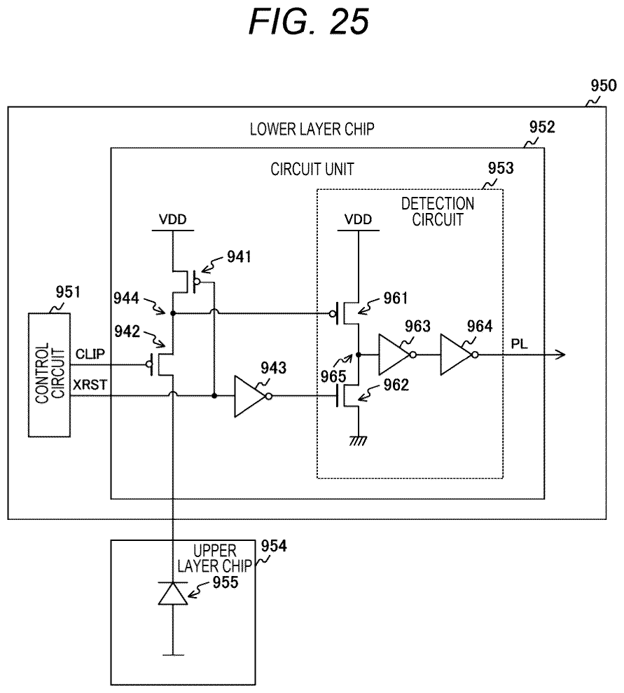

FIG. 25 is a circuit diagram illustrating a configuration example of a pixel according to the tenth embodiment.

In the drawing, this solid-state imaging device includes an upper layer chip 954 and a lower layer chip 950. The upper layer chip 954 is stacked on the lower layer chip 950.

On the upper layer chip 954, a SPAD 955 is formed for each pixel. On the lower layer chip 950, a control circuit 951 and a circuit unit 952 are formed. The circuit unit 952 includes a clipping transistor 942, an inverter 943, a recharge transistor 941, and a detection circuit 953. As the clipping transistor 942 and the recharge transistor 941, for example, p-channel metal oxide semiconductor (pMOS) transistors are used.

An anode of the SPAD 955 is connected to a predetermined potential lower than a power supply voltage VDD, and a cathode is connected to the clipping transistor 942.

The clipping transistor 942 and the recharge transistor 941 are connected in series between the power supply voltage VDD and the cathode of the SPAD 955 with the recharge transistor 941 on a power supply voltage VDD side. A detection node 944 is provided for the connection of the clipping transistor 942 and the recharge transistor 941.

A control signal CLIP from the control circuit 951 is input to a gate of the clipping transistor 942. A control signal XRST is input from the control circuit 951 to a gate of the recharge transistor 941 and the inverter 943. The inverter 943 inverts the control signal XRST and supplies the inverted signal to the detection circuit 953.

The detection circuit 953 detects incidence of photons and generates pulse signals PL. The detection circuit 953 includes a pMOS transistor 961, an n-channel MOS (nMOS) transistor 962, and inverters 963 and 964.

The pMOS transistor 961 and the nMOS transistor 962 are connected in series between the power supply voltage VDD and the ground voltage with the pMOS transistor 961 on the power supply voltage VDD side. A gate of the pMOS transistor 961 is connected to the detection node 944, and an inverted signal from the inverter 943 is input to a gate of the nMOS transistor 962.

The inverter 963 inverts a signal of a potential of a connection node 965 between the pMOS transistor 961 and the nMOS transistor 962. The inverter 964 inverts the inverted signal from the inverter 963 and supplies the inverted signal to a counter as a pulse signal PL. The counter is provided for each pixel. The counter may be formed in the circuit unit 952. As the counter, any of the counter circuits according to the first to sixth embodiments described above may be used.

Furthermore, setting information for controlling the pixel is input to the control circuit 951. The setting information includes setting values of a measurement period and the number of cycles. Here, the measurement period is a period of measuring incidence of photons, and the number of cycles indicates the number of times that control in the measurement period is repeated. Since the measurement is performed over an exposure period, when the setting value of the measurement period is A and the setting value of the number of cycles is a, A×a is the same value as the exposure period.

Within the measurement period, the control circuit 951 sets the control signal CLIP to a high level and then to a low level. During a period (hereinafter referred to as a standby period) in which the control signal CLIP is at the high level in the measurement period, the detection node 944 is disconnected from the cathode of the SPAD 955. During a period (hereinafter referred to as a connection period) in which the control signal CLIP is at the low level in the measurement period, on the other hand, the detection node 944 is connected to of the SPAD 955.

When photons are incident during the standby period, avalanche multiplication occurs in the SPAD 955, and a cathode potential drops to a certain potential. The clipping transistor 942 connects the detection node 944 to the SPAD 955 in the subsequent connection period. Therefore, in a case where photons are incident during the standby period, charges are transferred to the detection node 944 during the connection period, and the pulse signal PL goes to the high level.

Furthermore, the control circuit 951 sets the control signal XRST to the low level over a predetermined period from a predetermined recharge start timing within the connection period. As a result, the recharge transistor 941 supplies the power supply voltage VDD to the detection node 944. Since the detection node 944 is connected to the cathode, a recharge operation of returning the cathode potential to the power supply voltage VDD is performed. In addition, the detection circuit 953 is initialized by the low-level control signal XRST.

As described above, in the tenth embodiment described above, the SPAD 955 of each pixel is provided on the upper layer chip 954 and the circuit unit 952 is provided on the lower layer chip 950. As a result, it is possible to increase area of the SPAD 955 while suppressing an increase in chip size, and it is possible to improve sensitivity while downsizing the solid-state imaging device.

### 11. Eleventh Embodiment

In the first embodiment described above, the counter circuits configured by connecting 2-bit Johnson counters in n stages are employed for a solid-state imaging device. In this eleventh embodiment, counter circuits configured by connecting 2-bit Johnson counters in n stages are employed for a distance measurement device.

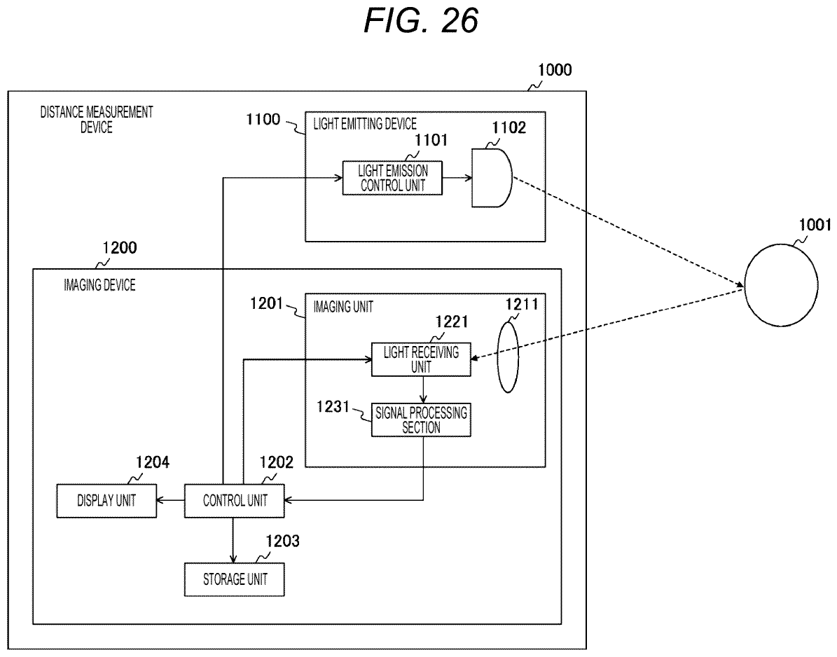

FIG. 26 is a block diagram illustrating a configuration example of the distance measurement device according to the eleventh embodiment.

In the drawing, a distance measurement device 1000 captures a distance image on the basis of, for example, time of flight (ToF). The distance image can be generated from a distance pixel signal based on a distance for each pixel in a depth direction from the distance measurement device 1000 to a subject 1001.

The distance measurement device 1000 includes a light emitting device 1100 and an imaging device 1200. The light emitting device 1100 includes a light emission control unit 1101 and a light emitting unit 1102.

The light emission control unit 1101 controls a light radiation pattern of the light emitting unit 1102 under the control of a control unit 1202. The light emitting unit 1102 emits light in a predetermined wavelength range under the control of the light emission control unit 1101. The predetermined wavelength range may be an infrared range. The light emitting unit 1102 may be a laser diode or a light emitting diode.

The imaging device 1200 receives, for each pixel, reflected light, which is light radiated from the light emitting device 1100 and reflected from the subject 1001, and generates a distance image. The imaging device 1200 includes an imaging unit 1201, a control unit 1202, a storage unit 1203, and a display unit 1204. The imaging unit 1201 includes an optical system 1211, a light receiving unit 1221, and a signal processing section 1231.

The optical system 1211 forms an image of incident light on a light receiving surface of the light receiving unit 1221. Note that the optical system 1211 may include a lens, an optical filter, a diaphragm, and the like.

The light receiving unit 1221 receives the reflected light reflected by the subject 1001. The light receiving unit 1221 may be a SPAD or a photodiode. Under the control of the control unit 1202, the light receiving unit 1221 receives reflected light from the subject 1001, and supplies a resultant pixel signal to the signal processing section 1231. This pixel signal represents a digital count value obtained by counting a time from when the light emitting device 1100 radiates radiation light to when the light receiving unit 1221 receives the radiation light. A light emission timing signal indicating the timing at which the light emitting unit 1102 emits light is also supplied from the control unit 1202 to the light receiving unit 1221. As a counter circuit that counts the time until the light receiving unit 1221 receives light, any of the counter circuits according to the first to sixth embodiments described above may be used.

The signal processing section 1231 processes the pixel signal supplied from the light receiving unit 1221 under the control of the control unit 1202. For example, the signal processing section 1231 detects a distance to the subject for each pixel on the basis of the pixel signal supplied from the light receiving unit 1221, and generates a distance image indicating the distance to the subject for each pixel. For example, the signal processing section 1231 obtains the time from when the light emitting unit 1102 emits light to when each pixel of the light receiving unit 1221 receives the light a plurality of times for each pixel. The signal processing section 1231 creates a histogram corresponding to the obtained time. Then, by detecting a peak of the histogram, the signal processing section 1231 determines the time until the light radiated from the light emitting unit 1102 is reflected from the subject 1001 and returns. Moreover, the signal processing section 1231 performs calculation for obtaining the distance to the object on the basis of the determined time and light speed. The signal processing section 1231 supplies the generated distance image to the control unit 1202.

The control unit 1202 controls the light emission control unit 1101 and the light receiving unit 1221. For example, the control unit 1202 supplies a radiation signal to the light emission control unit 1101 and supplies a light emission timing signal to the light receiving unit 1221. The light emitting unit 1102 emits radiation light in accordance with the radiation signal. The light emission timing signal may be the radiation signal supplied to the light emission control unit 1101. Furthermore, the control unit 1202 supplies the distance image obtained from the imaging unit 1201 to the display unit 1204 and causes the display unit 1204 to display the distance image. Moreover, the control unit 1202 stores the distance image obtained from the imaging unit 1201 in the storage unit 1203. The control unit 1202 may include a processor such as a central processing unit (CPU) or a graphics processing unit (GPU). Furthermore, the control unit 1202 may include a hardware circuit such as an application specific integrated circuit (ASIC) or a field programmable gate array (FPGA).

The display unit 1204 displays the distance image, a user interface screen, and the like. The display unit 1204 may be a liquid crystal display device or an organic EL display device. The storage unit 1203 stores the distance image, setting information used for the distance measurement, and the like. The storage unit 1203 may include a semiconductor memory such as a static random access memory (SRAM) or a dynamic random access memory (DRAM), or may include a storage device such as a hard disk device or a solid state drive (SSD).

As described above, in the eleventh embodiment described above, counter circuits configured by connecting 2-bit Johnson counters in n stages are employed for the distance measurement device 1000. As a result, it is possible to reduce power consumption of the counting operation at the time of distance measurement.

### 12. Example of Application to Mobile Body

The technology according to the present disclosure (present technology) can be applied to various kinds of products. For example, the technology according to the present disclosure may also be implemented as a device mounted on any type of mobile body such as an automobile, an electric automobile, a hybrid electric automobile, a motorcycle, a bicycle, a personal mobility, an airplane, a drone, a ship, and a robot.

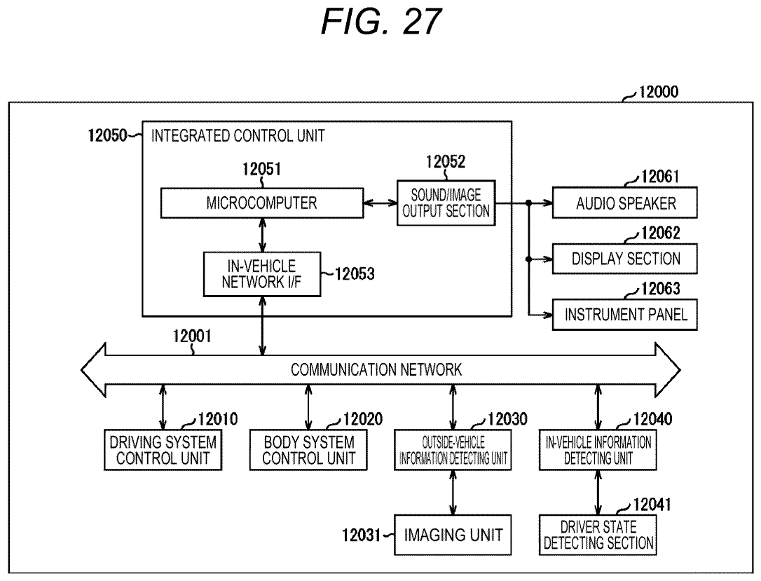

FIG. 27 is a block diagram illustrating an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 27, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and an in-vehicle network interface (I/F) 12053 are illustrated as functional configurations of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. Furthermore, the light received by the imaging section 12031 may be visible light, or may be invisible light such as infrared rays.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the vehicle exterior information acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 27, an audio speaker 12061, a display section 12062, and an instrument panel 12063 are illustrated as the output device. The display section 12062 may, for example, include at least one of an on-board display and a head-up display.

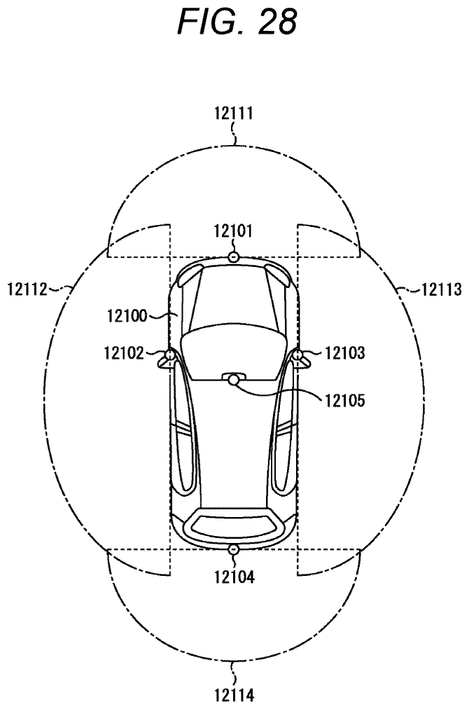

FIG. 28 is a diagram illustrating an example of an installation position of the imaging section 12031.

In FIG. 28, the imaging section 12031 includes imaging sections 12101, 12102, 12103, 12104, and 12105.

The imaging sections 12101, 12102, 12103, 12104, 12105 are provided, for example, at positions such as a front nose, a sideview mirror, a rear bumper, a back door, and an upper portion of a windshield in the interior of a vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 28 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the above, an example has been described of the vehicle control system to which the technology according to the present disclosure is applicable. The technology of the present disclosure can be applied to the imaging section 12031 among the components described above. Specifically, for example, the above-described solid-state imaging device can be applied to the imaging section 12031. By applying the technology according to the present disclosure to the vehicle control system 12000, power consumption can be reduced.

Note that the embodiments described above illustrate examples for embodying the present technology, and the matters in the embodiments and the matters specifying the invention in the claims have correspondence relationships. Similarly, the respective matters specifying the invention in the claims and the respective matters with the same names in the embodiments of the present technology have correspondence relationships. The present technology, however, is not limited to the embodiments, and can be implemented by making various modifications to the embodiments without departing from the scope of the present technology. Furthermore, effects described in the present specification are merely examples and not limited, and other effects may be provided.

Note that the present technology can also have the following configurations.

(1) A photodetection device including:
a light receiving unit that is arranged in a row direction and a column direction in a maritox and that outputs pulses generated in accordance with incidence of photons; and
a counter circuit that counts the pulses output from the light receiving unit, in which
the counter circuit includes
a plurality of 2-bit Johnson counters whose states transition on a basis of a transition input, and
a second bit of a count output of a 2-bit Johnson counter at a preceding stage is used as the transition input of a 2-bit Johnson counter at a subsequent stage.

(2) The photodetection device according to (1), in which
the 2-bit Johnson counters each include flip-flops connected in two stages, and
in each of the plurality of 2-bit Johnson counters, an inverted value of an output of a flip-flop at a subsequent stage is used as an input of a flip-flop at a preceding stage.

(3) The photodetection device according to (2), further including:
an inverter connected between the output of the flip-flop at the subsequent stage and the input of the flip-flop at the preceding stage.

(4) The photodetection device according to (1), in which
the 2-bit Johnson counters each include flip-flops connected in two stages, and
in each of the plurality of 2-bit Johnson counters, a value held in a flip-flop at a subsequent stage as an inverted value of an output of the flip-flop at the subsequent stage is used as an input of a flip-flop at a preceding stage.

(5) The photodetection device according to (4), in which
in each of the plurality of 2-bit Johnson counters, a value held in the flip-flop at the preceding stage as an inverted value of an output of the flip-flop at the preceding stage and the value held in the flip-flop at the subsequent stage as the inverted value of the output of the flip-flop at the subsequent stage are used as an output of the counter circuit.

(6) The photodetection device according to (4) or (5), in which
the flip-flop at the preceding stage includes
a first latch circuit and
a second latch circuit connected at a subsequent stage of the first latch circuit, and
the flip-flop at the subsequent stage includes
a third latch circuit and
a fourth latch circuit connected at a subsequent stage of the third latch circuit.

(7) The photodetection device according to (6), in which
the first latch circuit includes
a first inverter circuit that inverts an input,
a second inverter circuit that is connected in anti-parallel to the first inverter circuit and that inverts an input on a basis of the transition input, and
a first switch circuit that is connected at a preceding stage of the first inverter circuit and that opens and closes on a basis of the transition input,
the second latch circuit includes
a third inverter circuit that inverts an input,
a fourth inverter circuit that is connected in anti-parallel to the third inverter circuit and that inverts an input on a basis of the transition input, and
a second switch circuit that is connected at a preceding stage of the third inverter circuit and that opens and closes on a basis of the transition input,
the third latch circuit includes
a fifth inverter circuit that inverts an input,
a sixth inverter circuit that is connected in anti-parallel to the fifth inverter circuit and that inverts an input based on the transition input, and
a third switch circuit that is connected at a preceding stage of the fifth inverter circuit and that opens and closes on a basis of the transition input, and
the fourth latch circuit includes
a seventh inverter circuit that inverts an input,
an eighth inverter circuit that is connected in antiparallel to the seventh inverter circuit and that inverts an input based on the transition input, and
a fourth switch circuit that is connected at a preceding stage of the seventh inverter circuit and that opens and closes on a basis of the transition input.

(8) The photodetection device according to (7), in which
each of the first and fifth inverter circuits is a NAND circuit to which a reset signal is input,
each of the third and seventh inverter circuits is an inverter,
each of the second, fourth, sixth, and eighth inverter circuits is a clocked inverter, and
each of the first to fourth switch circuits is a transmission gate.

(9) The photodetection device according to (8), further including:
a capacitor connected to an input terminal of the flip-flop at the preceding stage.

(10) The photodetection device according to (9), in which
a capacitance value of the capacitor is larger than a capacitance value of a capacitor added to an output of the first switch circuit.

(11) The photodetection device according to (9) or (10), in which
the capacitor is a metal capacitor, a gate capacitor whose gate is connected to the input terminal of the flip-flop at the preceding stage, or a gate capacitor whose source/drain is connected to the input terminal of the flip-flop at the preceding stage.

(12) The photodetection device according to any one of (9) to (11), in which
the capacitor is a variable capacitor whose capacitance value is variable.

(13) The photodetection device according to (7), in which
each of the first and fifth inverter circuits is a NAND circuit to which a reset signal is input,
each of the third and seventh inverter circuits is an inverter,
each of the first switch circuit and the second, fourth, sixth, and eighth inverter circuits is a clocked inverter, and
each of the second to fourth switch circuits is a transmission gate.

(14) The photodetection device according to (7), in which
each of the first and fifth inverter circuits is a NAND circuit to which a reset signal is input,
each of the third and seventh inverter circuits is an inverter,
each of the second, fourth, and sixth inverter circuits is a clocked inverter,
the eighth inverter circuit is a series circuit of an inverter and a transmission gate, and
each of the first to fourth switch circuits is a transmission gate.

(15) The photodetection device according to (7), in which
each of the first and fifth inverter circuits is a NAND circuit to which a reset signal is input,
each of the third and seventh inverter circuits is an inverter,
each of the second and sixth inverter circuits is a clocked inverter,
each of the fourth and eighth inverter circuits is a series circuit of an inverter and a transmission gate, and
each of the first to fourth switch circuits is a transmission gate.

(16) The photodetection device according to any one of (1) to (15), in which
a transition input of the flip-flop at the preceding stage and a transition input of the flip-flop at the subsequent stage have phases opposite to each other.

(17) The photodetection device according to any one of (1) to (16), in which
the pulses generated in accordance with the incidence of photons are input to a first stage of the 2-bit Johnson counters.

(18) The photodetection device according to any one of (1) to (17), in which the number of states is given as 4n, where n is the number of stages of the 2-bit Johnson counters.

(19) The photodetection device according to any one of (1) to (18), in which
the counter circuit is disposed below the light receiving unit.

(20) A counter circuit including:
a plurality of 2-bit Johnson counters whose states transition on a basis of a transition input, in which
a second bit of a count output of a 2-bit Johnson counter at a preceding stage is used as the transition input of a 2-bit Johnson counter at a subsequent stage.

(21) A photodetection device including:
a light emitting element;
a light receiving element that outputs pulses generated in accordance with incidence of photons; and
a counter circuit that counts the pulses output from the light receiving element, in which
the counter circuit includes
a plurality of 2-bit Johnson counters whose states transition on a basis of a transition input, and
a second bit of a count output of a 2-bit Johnson counter at a preceding stage is used as the transition input of a 2-bit Johnson counter at a subsequent stage.

(22) The photodetection device according to any one of (1) to (19), in which
a period of a state transition of the 2-bit Johnson counter at the subsequent stage is four times a period of a state transition of the 2-bit Johnson counter at the preceding stage.

(23) The photodetection device according to any one of (1) to (19), in which
the light receiving unit includes a single photon avalanche diode (SPAD).

### REFERENCE SIGNS LIST

100 Imaging device
101 Optical system
102 Solid-state imaging device
103 Imaging control unit
104 Image processing unit
105 Storage unit
106 Display unit
107 Operation unit
108 Bus
110 Pixel
111 Pixel array unit
112 Control unit
113 Signal processing unit
121 SPAD
122 Quench resistor
123 Inverter
124 Counter circuit
125 Lower layer chip
126 Upper layer chip
127, 128 Pad electrode
131, 132, 141, 142 Latch circuit
201 to 203 2-bit Johnson counter
211, 221, 212, 222, 213, 223 Flip-flop
162, 182, 262, 282 Inverter
151, 161, 171, 181, 251, 261, 271, 281 Transmission gate
153, 163, 173, 183, 253, 263, 273, 283 Clocked inverter
152, 172, 252, 272 NAND circuit

1. A photodetection device comprising:
a light receiving unit that is arranged in a row direction and a column direction in a maritox and that outputs pulses generated in accordance with incidence of photons; and
a counter circuit that counts the pulses output from the light receiving unit, wherein
the counter circuit includes
a plurality of 2-bit Johnson counters whose states transition on a basis of a transition input, and
a second bit of a count output of a 2-bit Johnson counter at a preceding stage is used as the transition input of a 2-bit Johnson counter at a subsequent stage.

2. The photodetection device according to claim 1, wherein
the 2-bit Johnson counters each include flip-flops connected in two stages, and
in each of the plurality of 2-bit Johnson counters, an inverted value of an output of a flip-flop at a subsequent stage is used as an input of a flip-flop at a preceding stage.

3. The photodetection device according to claim 2, further comprising:
an inverter connected between the output of the flip-flop at the subsequent stage and the input of the flip-flop at the preceding stage.

4. The photodetection device according to claim 1, wherein
the 2-bit Johnson counters each include flip-flops connected in two stages, and
in each of the plurality of 2-bit Johnson counters, a value held in a flip-flop at a subsequent stage as an inverted value of an output of the flip-flop at the subsequent stage is used as an input of a flip-flop at a preceding stage.

5. The photodetection device according to claim 4, wherein
in each of the plurality of 2-bit Johnson counters, a value held in the flip-flop at the preceding stage as an inverted value of an output of the flip-flop at the preceding stage and the value held in the flip-flop at the subsequent stage as the inverted value of the output of the flip-flop at the subsequent stage are used as an output of the counter circuit.

6. The photodetection device according to claim 4, wherein
the flip-flop at the preceding stage includes
a first latch circuit and
a second latch circuit connected at a subsequent stage of the first latch circuit, and
the flip-flop at the subsequent stage includes
a third latch circuit and
a fourth latch circuit connected at a subsequent stage of the third latch circuit.

7. The photodetection device according to claim 6, wherein
the first latch circuit includes
a first inverter circuit that inverts an input,
a second inverter circuit that is connected in anti-parallel to the first inverter circuit and that inverts an input on a basis of the transition input, and
a first switch circuit that is connected at a preceding stage of the first inverter circuit and that opens and closes on a basis of the transition input,
the second latch circuit includes
a third inverter circuit that inverts an input,
a fourth inverter circuit that is connected in anti-parallel to the third inverter circuit and that inverts an input on a basis of the transition input, and
a second switch circuit that is connected at a preceding stage of the third inverter circuit and that opens and closes on a basis of the transition input,
the third latch circuit includes
a fifth inverter circuit that inverts an input,
a sixth inverter circuit that is connected in anti-parallel to the fifth inverter circuit and that inverts an input based on the transition input, and
a third switch circuit that is connected at a preceding stage of the fifth inverter circuit and that opens and closes on a basis of the transition input, and
the fourth latch circuit includes
a seventh inverter circuit that inverts an input,
an eighth inverter circuit that is connected in antiparallel to the seventh inverter circuit and that inverts an input based on the transition input, and
a fourth switch circuit that is connected at a preceding stage of the seventh inverter circuit and that opens and closes on a basis of the transition input.

8. The photodetection device according to claim 7, wherein
each of the first and fifth inverter circuits is a NAND circuit to which a reset signal is input,
each of the third and seventh inverter circuits is an inverter,
each of the second, fourth, sixth, and eighth inverter circuits is a clocked inverter, and
each of the first to fourth switch circuits is a transmission gate.

9. The photodetection device according to claim 8, further comprising:
a capacitor connected to an input terminal of the flip-flop at the preceding stage.

10. The photodetection device according to claim 9, wherein
a capacitance value of the capacitor is larger than a capacitance value of a capacitor added to an output of the first switch circuit.

11. The photodetection device according to claim 9, wherein
the capacitor is a metal capacitor, a gate capacitor whose gate is connected to the input terminal of the flip-flop at the preceding stage, or a gate capacitor whose source/drain is connected to the input terminal of the flip-flop at the preceding stage.

12. The photodetection device according to claim 9, wherein
the capacitor is a variable capacitor whose capacitance value is variable.

13. The photodetection device according to claim 7, wherein
each of the first and fifth inverter circuits is a NAND circuit to which a reset signal is input,
each of the third and seventh inverter circuits is an inverter,
each of the first switch circuit and the second, fourth, sixth, and eighth inverter circuits is a clocked inverter, and
each of the second to fourth switch circuits is a transmission gate.

14. The photodetection device according to claim 7, wherein
each of the first and fifth inverter circuits is a NAND circuit to which a reset signal is input,
each of the third and seventh inverter circuits is an inverter,
each of the second, fourth, and sixth inverter circuits is a clocked inverter,
the eighth inverter circuit is a series circuit of an inverter and a transmission gate, and
each of the first to fourth switch circuits is a transmission gate.

15. The photodetection device according to claim 7, wherein
each of the first and fifth inverter circuits is a NAND circuit to which a reset signal is input,
each of the third and seventh inverter circuits is an inverter,
each of the second and sixth inverter circuits is a clocked inverter,
each of the fourth and eighth inverter circuits is a series circuit of an inverter and a transmission gate, and
each of the first to fourth switch circuits is a transmission gate.

16. The photodetection device according to claim 2, wherein
a transition input of the flip-flop at the preceding stage and a transition input of the flip-flop at the subsequent stage have phases opposite to each other.

17. The photodetection device according to claim 1, wherein
the pulses generated in accordance with the incidence of photons are input to a first stage of the 2-bit Johnson counters.

18. The photodetection device according to claim 1, wherein
the number of states is given as 4n, where n is the number of stages of the 2-bit Johnson counters.

19. The photodetection device according to claim 1, wherein
the counter circuit is disposed below the light receiving unit.

20. A counter circuit comprising:
a plurality of 2-bit Johnson counters whose states transition on a basis of a transition input, wherein
a second bit of a count output of a 2-bit Johnson counter at a preceding stage is used as the transition input of a 2-bit Johnson counter at a subsequent stage.
